(19) United States
(12) Patent Application Publication
(10) Pub. No.: US 2023/0341448 A1
(43) Pub. Date: Oct. 26, 2023

(54) ACCURATE DETERMINATION OF RADIO FREQUENCY POWER THROUGH DIGITAL INVERSION OF SENSOR EFFECTS

(71) Applicant: Lam Research Corporation, Fremont, CA (US)

(72) Inventors: Ashish Saurabh, Portland, OR (US); Karl Frederick Leeser, West Linn, OR (US)

(21) Appl. No.: 18/002,733

(22) PCT Filed: Jun. 22, 2021
(86) PCT No.: PCT/US2021/038457

§ 371 Date: Dec. 21, 2022

(30) Foreign Application Priority Data
Jun. 29, 2020 (IN) 202031027674

(51) Int. Cl. G01R 23/163; G01R 19/252; G01R 23/12

(52) U.S. Cl. CPC G01R 23/163; G01R 19/252; G01R 23/12

(57) ABSTRACT

An apparatus may include one or more measurement sensors, which may measure power coupled to one or more process stations of the apparatus. The apparatus may additionally include one or more analog-to-digital converters coupled to an output port of a corresponding one of the one or more measurement sensors, which may provide a digital representation of a RF signal measured by the one or more measurement sensors. A processor, coupled to a memory, may determine a crossing of the digital representation of the signal with a reference signal level and may thus determine a frequency content of the RF signal and the characteristic, which may permit the nulling out of phase lag of the one or more measurement sensors.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Fabrication of integrated circuit devices may involve the processing of semiconductor wafers in a semiconductor processing chamber. Typical processes may involve deposition, in which a semiconductor material may be deposited, such as in a layer-by-layer fashion, as well as removal (e.g., etching) of material in certain regions of the semiconductor wafer. In commercial scale manufacturing, each wafer contains many copies of a set of semiconductor devices, and many wafers may be utilized to achieve the required volumes of semiconductor devices. Accordingly, the commercial viability of a semiconductor processing operation may depend, at least to some extent, upon within-wafer uniformity and upon wafer-to-wafer repeatability of process conditions. Consequently, efforts are made to ensure that each portion of a given wafer, as well as each wafer processed in a semiconductor processing chamber, is subjected to tightly-controlled processing conditions. Variations in processing conditions can bring about undesirable variations in deposition and etch rates, which, in turn, may bring about unacceptable variations in an overall fabrication process. Such variations may degrade circuit performance which, in turn, may give rise to unacceptable variations in performance of higher-level systems that utilize the integrated circuit devices. Accordingly, techniques for monitoring semiconductor processes with increased granularity, as well as an ability to make fine adjustments to process variables during fabrication, continues to be an active area of investigation.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

In an embodiment, an apparatus, such as an apparatus to null out of phase lag of one or more measurement sensors utilized in a multi-station integrated circuit fabrication chamber, includes one or more measurement sensors disposed to measure voltage applied to, or current coupled to, the multi-station integrated circuit fabrication chamber. The apparatus also includes one or more analog-to-digital converters, coupled to an output port of a corresponding one of the one or more measurement sensors, to provide a digital representation of a radio frequency (RF) signal measured by the one or more measurement sensors. The apparatus also includes a processor, coupled to a memory, configured to compute a frequency response (which may be formulated as a frequency response matrix) from the digital representation of the measured RF signal. The apparatus also includes a digital inverter to divide or to multiply a digital representation of the RF signal measured by elements of the frequency response matrix. In an embodiment, the apparatus may auto correct a nulled-out phase lag.

In some embodiments, the digital inverter includes a digital voltage signal inverter or a digital current signal inverter. In some embodiments, the processor coupled to the memory is configured to compute the elements of the frequency response (which may be formulated as a frequency response matrix) during a calibration phase, and compute the inversion of the frequency response (which may be formulated as a frequency response matrix) to provide the phase lag of the one or more measurement sensors, which occurs during a process performed by the multi-station integrated circuit fabrication chamber. In some embodiments, the digital inverter includes two or more Fast Fourier Transform blocks arranged in parallel. In some embodiments, each of the two or more Fast Fourier Transform blocks is arranged in parallel with a corresponding delay circuit. In some embodiments, the digital inverter includes a logic circuit, which is configured to convey an output signal from the one or more measurement sensors to a first of the two or more Fast Fourier Transform blocks during a first clock portion and is configured to convey the output signal from the one or more measurement sensors to a second of the two or more Fast Fourier Transform blocks during a second clock portion. In some embodiments, the digital inverter includes a concatenation block configured to join output signal representations from the two or more Fast Fourier Transform blocks arranged in parallel into a single output signal representation. In some embodiments, the apparatus further includes a truncation block configured to truncate the size of the single output signal representation. In some embodiments, the truncation block includes a sliding window that is configured to adjust binary digits of the output signal representation.

In an embodiment, an apparatus is configured to null out a phase lag of a measurement sensor. The apparatus includes one or more analog-to-digital converters, coupled to an output port of a corresponding one of the one or more measurement sensors, to provide a digital representation of a radio frequency (RF) signal measured by the one or more measurement sensors. The apparatus also includes a processor, coupled to a memory, configured to compute a frequency response from the digital representation of the measured RF signal measured. The apparatus also includes a digital inverter to divide or multiply a digital representation of the RF signal measured by elements of the frequency response matrix. In some embodiments, a frequency response may be formulated as a frequency response matrix.

In some embodiments, the apparatus is adapted to null out a phase lag of one or more measurement sensors and includes an analog-to-digital converter to convert an analog signal, obtained from one or more output ports of a corresponding number of the one or more measurement sensors to measure voltage applied to (or current coupled to) a multi-station integrated circuit fabrication chamber, to a digital representation. The apparatus also includes a detector to detect the frequency content of the output signals of the one or more measurement sensors. The apparatus also includes a processor coupled to a memory to determine, in response to detecting the frequency content of the output signals of the one or more measurement sensors, a frequency response function of the one or more measurement sensors, the processor coupled to the memory additionally to null out the phase lag of the one or more measurement sensors by inverting a frequency response function of the one or more measurement sensors.

In some embodiments, determining the frequency response (which may include determining coefficients of a frequency response matrix) includes determining a crossing of the digital representation of the signal with a reference signal level. In some embodiments, the apparatus may also include determine, utilizing the crossing of the digital representation of the signal measured by the one or more measurement sensors, a frequency content of the RF signal and the nulled-out phase lag of the one or more measurement sensors. In some embodiments, the crossing may correspond to crossing a RF signal ground. In some embodiments, the one or more measurement sensors include a capacitive voltage transformer operating at any frequency between about 300 kHz and 100 MHz. In some embodiments, the one or more measurement sensors includes a current measurement sensor operating at a frequency of between about 300 kHz and about 100 MHz. In some embodiments, the nulling out of phase lag of the one or more measurement sensors corresponds to canceling phase lag introduced by the one or more measurement sensors. In some embodiments, the frequency response, which may be formulated as a frequency response matrix, forms a frequency response function. In some embodiments, the processor is further configured to provide an estimate of RF power coupled to the multi-station integrated circuit fabrication chamber utilizing a signal received from the one or more measurement sensors that is advanced by an amount corresponding to the phase lag.

In an embodiment, an apparatus is adapted to null out a phase lag of one or more measurement sensors, including an analog-to-digital converter to convert an analog signal, obtained from one or more output ports of a corresponding number of the one or more measurement sensors to measure voltage applied to (or current coupled to) a multi-station integrated circuit fabrication chamber, to a digital representation. The apparatus also includes a detector to detect the frequency content of the output signals of the one or more measurement sensors. The apparatus also includes a processor coupled to a memory to determine, in response to detecting the frequency content of the output signals of the one or more measurement sensors, a frequency response function of the one or more measurement sensors, the processor coupled to the memory additionally to null out the phase lag of the one or more measurement sensors by inverting a frequency response function of the one or more measurement sensors.

In some embodiments, detecting the frequency content of the output signals of the one or more sensors includes detecting a crossing of the digital representation of the obtained analog signal with a reference signal. In some embodiments, the reference signal corresponds to a radio frequency (RF) ground. In some embodiments, a first measurement sensor of the corresponding number of the one or more measurement sensors includes a voltage measurement sensor. In some embodiments, a second measurement sensor of the corresponding number of measurement sensors includes a current measurement sensor. In some embodiments, the processor applies a phase lag correction to measurements performed by the voltage measurement sensor and the current measurement sensor to obtain a corrected instantaneous voltage measurement and corrected instantaneous current measurement. In some embodiments, the processor further operates to compute RF power delivered to the multi-station integrated circuit fabrication chamber by computing the product of a corrected instantaneous voltage and a corrected instantaneous current. In some embodiments, the processor further operates to compute a moving average of successive computations of RF power delivered to the multi-station integrated circuit fabrication chamber to estimate average RF power delivered to the multi-station integrated circuit fabrication chamber. In some embodiments, the processor further operates to compute real-time power delivered to the multi-station integrated circuit fabrication chamber utilizing real-time phase-corrected instantaneous voltage and real-time phase-corrected instantaneous current. In some embodiments, the processor further operates to modify an amount of power generated by a power generator, for coupling to the multi-station integrated circuit fabrication chamber, responsive to computing the real-time power delivered. In some embodiments, the phase lag of the one or more measurement sensors is determined in terms of clock periods.

In an embodiment, an apparatus is configured to estimate radio frequency (RF) power coupled to a load, including a current sensor having a current sensor frequency response function and a voltage sensor having a voltage sensor frequency response function. The apparatus also includes a first analog-to-digital converter coupled to an output port of the current sensor. The apparatus also includes a second analog-to-digital converter coupled to an output port of the voltage sensor; and a processor coupled to a memory to obtain digital representations of instantaneous current and to obtain digital representations of instantaneous voltage, to obtain a phase lag of the instantaneous current and the instantaneous voltage, and to invert the frequency response function of the current sensor and the frequency response function of the voltage sensor to counteract for the obtained phase lag of the instantaneous current and the instantaneous voltage. In some embodiments, the current sensor of the apparatus includes an inductive current transformer. In some embodiments, the voltage sensor includes a capacitive voltage transformer. In some embodiments, the current sensor and the voltage sensor operate at any frequency between about 300 kHz and about 100 MHz.

In an embodiment, an apparatus is adapted to null out a phase lag of one or more measurement sensors, including: an analog-to digital converter to convert an analog signal, obtained from one or more output ports of a corresponding number of the one or more measurement sensors to measure voltage applied to or current coupled to a multi-station integrated circuit fabrication chamber, to a digital representation. The apparatus also includes a detector to detect a sensor response characteristic from the digital representation of the obtained analog signal. The apparatus also includes a processor coupled to a memory to determine, in response to detecting the sensor response characteristic, at least one frequency component present in the digital representation of the obtained analog signal, the processor coupled to the memory additionally to null out the phase lag of the one or more measurement sensors by inverting a frequency response function of the one or more measurement sensors.

In some embodiments, the detector of the apparatus detects the sensor response characteristic by determining a crossing of the digital representation of the obtained analog signal with a reference signal. In some embodiments, the detector detects the sensor response characteristic utilizing an analog representation of the reference signal. In some embodiments, the detector detects the sensor response characteristic utilizing a digital representation of the reference signal. In some embodiments, the processor is coupled to the memory and is configured to determine the at least one frequency component present in the digital representation of the obtained analog signal in response to detecting the crossing of the digital representation of the obtained analog signal with the reference signal. In some embodiments, the processor coupled to the memory performs the inverting of the frequency response function of the one or more measurement sensors in the frequency domain. In some embodiments, the processor coupled to the memory performs the inverting of the frequency response function of the one or more measurement sensors in the time domain.

### BRIEF DESCRIPTION OF THE DRAWINGS

The various embodiments disclosed herein are illustrated by way of example, and not by way of limitation, in the figures of the accompanying drawings, in which like reference numerals refer to similar elements.

FIG. 1A shows a substrate processing apparatus for depositing or etching a film on or over a semiconductor substrate utilizing any number of processes, according to various embodiments.

FIG. 1B depicts a schematic view of an embodiment of a multi-station processing tool.

FIG. 2A is a schematic diagram showing the phase lag in the measurement of a radio frequency (RF) signal, according to an embodiment.

FIG. 2B is a schematic diagram showing an apparatus that may be utilized to characterize waveforms V_{RF} and I_{RF} of FIG. 2A according to an embodiment.

FIG. 2C is a schematic diagram showing additional details of an apparatus used in developing a lookup table of values of phase lag introduced by devices utilized in measurement of a RF signal, according to an embodiment that utilizes a time domain approach.

FIG. 3 is a schematic diagram of an apparatus used in RF power measurement in a multi-station integrated circuit fabrication chamber, according to an embodiment that utilizes a time domain approach.

FIG. 4 is a flowchart for a method of determining a phase lag of one or more measurement sensors, according to an embodiment that utilizes a time domain approach.

FIG. 5 is a high-level schematic diagram of an apparatus used in RF power measurement in a multi-station integrated circuit fabrication chamber according to an embodiment that utilizes a frequency domain approach.

FIG. 6 is a schematic diagram of an apparatus used to perform digital inversion of measurement signals from a multi-station integrated circuit fabrication chamber according to an embodiment that utilizes a frequency domain approach.

FIG. 7 is a flowchart for a method of computing RF power from voltage signals from a multi-station integrated circuit fabrication chamber according to an embodiment that utilizes a frequency domain approach.

FIG. 8 is a flowchart for a method of computing RF power from current signals from a multi-station integrated circuit fabrication chamber according to an embodiment that utilizes a frequency domain approach.

### DETAILED DESCRIPTION

In particular embodiments, determination of phase lag in radio frequency (RF) signal sensors may be utilized in conjunction with a variety of equipment utilized in the fabrication of integrated circuits, such as equipment related to plasma-based integrated circuit fabrication. For example, in a multi-station integrated circuit fabrication chamber, in which multiple semiconductor wafers simultaneously undergo deposition or etching processes, determination of phase lag in voltage and current signals provided to the fabrication chamber may allow precise computation, in real-time, of RF power conveyed to the stations of the fabrication chamber. Accordingly, in the event that conditions within the fabrication chamber give rise to changes in the input impedance of the fabrication chamber (which may cause power directed to the input port of the fabrication chamber to be reflected back to the RF power source), component values of an input impedance matching network may be adjusted by precise amounts in response to such changes. Such precise adjustment of component values of the impedance matching network may enable coupling of a specific quantity of power into the fabrication chamber while minimizing power reflected from the fabrication chamber. Consequently, semiconductor processes conducted within a multi-station fabrication chamber may be performed with greater accuracy which may, in turn, result in lower defect ratios and higher yields of devices formed utilizing the fabrication chamber.

In certain embodiments, determination of phase lag in RF signal sensors may allow precise characterization of current and voltage parameters and/or waveforms that bring about undesirable or abnormal operation of an integrated circuit fabrication chamber. For example, if plasma within a fabrication chamber undergoes formation of an electric arc, which may result in an unwanted formation of compounds in a gaseous or plasma state within the fabrication chamber, precise current and/or voltage conditions may be detected and characterized. Such characterization may operate to prevent future occurrences of arcing, perhaps by modifying current and/or voltage parameters that may have previously led to arcing within the fabrication chamber.

Particular embodiments may represent improvements over other approaches of measuring or estimating phase lag in RF signal sensors for use in integrated circuit fabrication processes. For example, in one such approach, phase lag of RF signal sensors may be estimated by utilizing two-dimensional calibration circuits, which may be activated and analyzed in a post-processing environment. Consequently, effects of voltage and/or current sensor measurement errors may go unnoticed until after integrated circuit processing operations are completed, which may allow abnormal conditions to persist within an integrated circuit processing chamber for extended periods of time.

Further, such analog postprocessing utilizing calibration circuits may not predict and/or characterize RF signal sensor phase lag over all frequencies of interest, such as frequencies as low as about 300 kHz and frequencies as high as about 100 MHz. Accordingly, in an effort to characterize phase lag in RF signal sensors, a group of calibration circuits may be constructed, wherein each calibration circuit of the group may provide phase lag information over a specified portion of a about 300 kHz to about 100 MHz range of frequencies. Consequently, characterization of phase lag over such a wide range of frequency may require construction of numerous calibration circuits.

Certain embodiments and implementations may be utilized in conjunction with a number of wafer fabrication processes, such as various plasma-enhanced atomic layer deposition (ALD) processes (e.g., ALD1, ALD2), various plasma-enhanced chemical vapor deposition (e.g., CVD1, CVD2, CVD3) processes, or may be utilized on-the-fly during single deposition processes. In certain embodiments, a RF power generator having multiple output ports may be utilized at any signal frequency, such as at frequencies between about 300 kHz and about 60 MHz, which may include frequencies of about 400 kHz, about 1 MHz, about 2 MHz, about 13.56 MHz, and about 27.12 MHz. However, in other embodiments, RF power generators having multiple output ports may operate at any signal frequency, which may include relatively low frequencies, such as between about 50 kHz and about 300 kHz, as well as higher signal frequencies, such as frequencies between about 60 MHz and about 100 MHz, virtually without limitation.

It should be noted that although particular embodiments described herein may show and/or describe multi-station semiconductor fabrication chambers comprising 4 process stations, claimed subject matter may embrace multi-station integrated circuit fabrication chambers comprising any number of process stations. Thus, in certain embodiments, individual output ports of a RF power generator having multiple output ports may be assigned to a process station of a multi-station fabrication chamber having, for example, 2 process stations or 3 process stations. In other embodiments individual output ports of a RF power generator having multiple output ports may be assigned to process stations of a multi-station integrated circuit fabrication chamber having a larger number of process stations, such as 5 process stations, 6 process stations, 8 process stations, 10 process stations, or any other number of process stations, virtually without limitation.

Additionally, although particular embodiments described herein may show and/or describe utilization of a single, relatively low frequency RF signal, such as a frequency of between about 300 kHz and about 2 MHz, as well as a single, relatively high-frequency RF signal, such as a frequency of between about 2 MHz and about 100 MHz, claimed subject matter may embrace the use of any number of frequencies below about 2 MHz as well as any number of frequencies above about 2 MHz. Further, although particular embodiments, such as described herein, may relate to measurement of characteristics of signals coupled to a multi-station integrated circuit fabrication chamber, which may include voltage and current signals coupled to a fabrication chamber utilizing a two-conductor transmission line (e.g., a coaxial cable), claimed subject matter is intended to embrace measurement of other signal characteristics. For example, particular embodiments may relate to measurement of characteristics such as electric field strength and/or magnetic field strength in a rectangular or circular waveguide, a strip line, or any other type of transmission media coupled to a multi-station integrated circuit fabrication chamber.

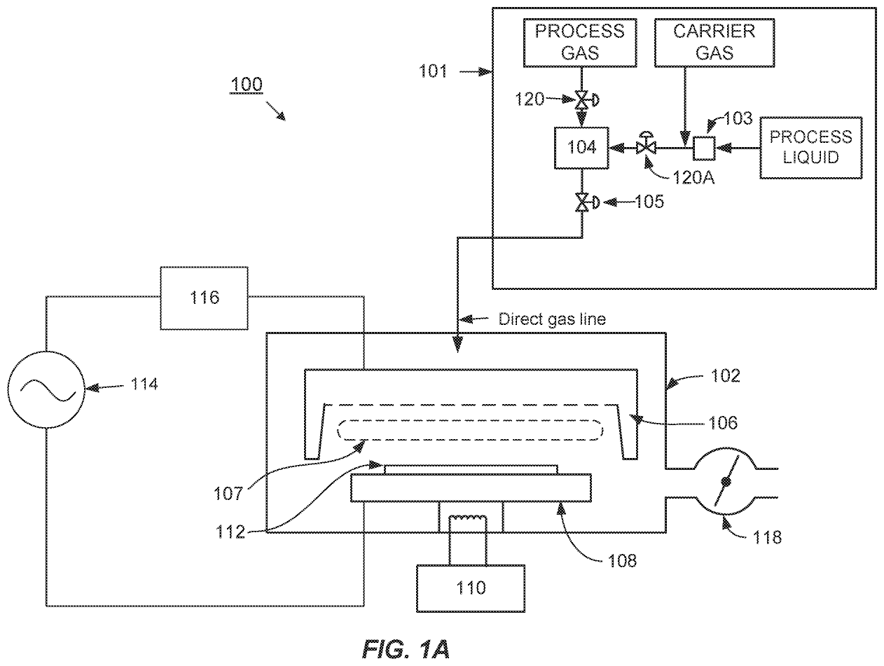

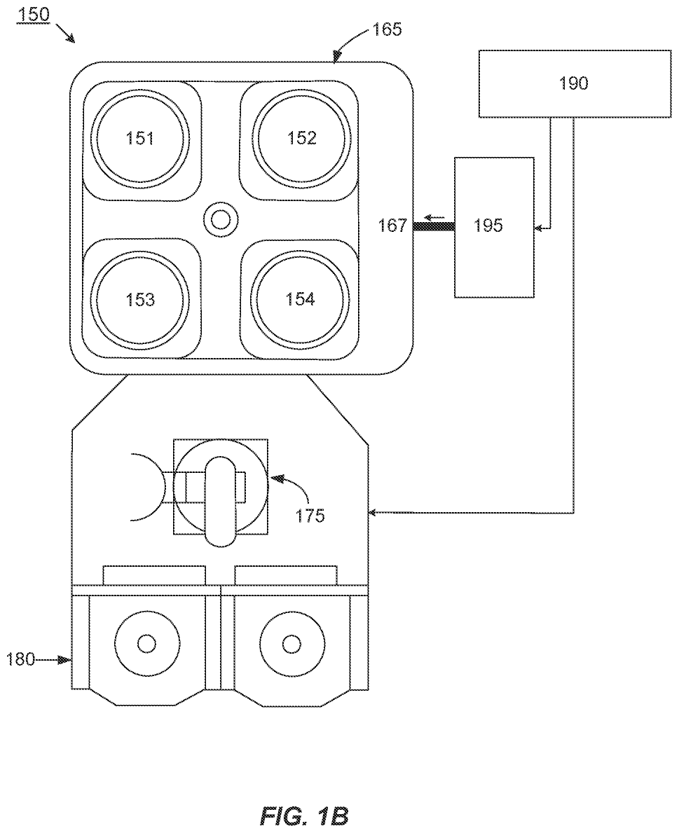

Manufacture of semiconductor devices typically involves depositing or etching of one or more thin films on or over a planar or non-planar substrate in an integrated fabrication process. In some aspects of an integrated process, it may be useful to deposit thin films that conform to unique substrate topography. One type of reaction that is useful in many instances may involve chemical vapor deposition (CVD). In typical CVD processes, gas phase reactants introduced into stations of a reaction chamber simultaneously undergo a gas-phase reaction. The products of the gas-phase reaction deposit on the surface of the substrate. A reaction of this type may be driven by, or enhanced by, presence of a plasma, in which case the process may be referred to as a plasma-enhanced chemical vapor deposition (PECVD) reaction. As used herein, the term CVD is intended to include PECVD unless otherwise indicated. CVD processes have certain disadvantages that render them less appropriate in some contexts. For instance, mass transport limitations of CVD gas phase reactions may bring about deposition effects that exhibit thicker deposition at top surfaces (e.g., top surfaces of gate stacks) and thinner deposition at recessed surfaces (e.g., bottom corners of gate stacks). Further, in response to some semiconductor die having regions of differing device density, mass transport effects across the substrate surface may result in within-die and within-wafer thickness variations. Thus, during subsequent etching processes, thickness variations can result in over-etching of some regions and under-etching of other regions, which can degrade device performance and die yield. Another difficulty related to CVD processes is that such processes are often unable to deposit conformal films in high aspect ratio features. This issue can be increasingly problematic as device dimensions continue to shrink. These and other drawbacks of particular aspects of wafer fabrication processes are discussed in relation to FIG. 1A and FIG. 1B.

In another example, some deposition processes involve multiple film deposition cycles, each producing a discrete film thickness. For example, in atomic layer deposition (ALD), thickness of a deposited layer may be limited by an amount of one or more film precursor reactants, which may adsorb onto a substrate surface, so as to form an adsorption-limited layer, prior to the film-forming chemical reaction itself. Thus, a feature of ALD involves the formation of thin layers of film, such as layers having a width of a single atom or molecule, which are used in a repeating and sequential matter. As device and feature sizes continue to be reduced in scale, and as three-dimensional devices and structures become more prevalent in integrated circuit (IC) design, the capability of depositing thin conformal films (e.g., films of material having a uniform thickness relative to the shape of the underlying structure) continues to gain in importance. Thus, in view of ALD being a film-forming technique in which each deposition cycle operates to deposit a single atomic or molecular layer of material, ALD may be well-suited to the deposition of conformal films. Typical device fabrication processes involving ALD may include multiple ALD cycles, which may number into the hundreds or thousands, may then be utilized to form films of virtually any desired thickness. Further, in view of each layer being thin and conformal, a film that results from such a process may conform to a shape of any underlying device structure. In certain implementations, an ALD cycle may include the following steps:

Exposure of the substrate surface to a first precursor.

Purge of the reaction chamber in which the substrate is located.

Activation of a reaction of the substrate surface, typically with a plasma and/or a second precursor.

Purge of the reaction chamber in which the substrate is located.

The duration of each ALD cycle may typically be less than about 25 seconds or less than about 10 seconds or less than about 5 seconds. The plasma exposure step (or steps) of the ALD cycle may be of a short duration, such as a duration of about 1 second or less.

Turning now to the figures, FIG. 1A shows a substrate processing apparatus 100 for depositing films on or over a semiconductor substrate utilizing any number of processes, according to various embodiments. Processing apparatus 100 of FIG. 1A utilizes single process station 102 of a process chamber with a single substrate holder 108 (e.g., a pedestal) in an interior volume, which may be maintained under vacuum by vacuum pump 118. Showerhead 106 and gas delivery system 101, which may be fluidically coupled to the process chamber, may permit the delivery of film precursors, for example, as well as carrier and/or purge and/or process gases, secondary reactants, etc. Equipment utilized in the generation of plasma within the process chamber is also shown in FIG. 1A. The apparatus schematically illustrated in FIG. 1A may be adapted for performing, in particular, plasma-enhanced CVD.

In FIG. 1A, gas delivery system 101 includes a mixing vessel 104 for blending and/or conditioning process gases for delivery to showerhead 106. One or more mixing vessel inlet valves 120 may control introduction of process gases to mixing vessel 104. Particular reactants may be stored in liquid form prior to vaporization and subsequent delivery to process station 102 of a process chamber. The embodiment of FIG. 1A includes a vaporization point 103 for vaporizing liquid reactant to be supplied to mixing vessel 104. In some embodiments, vaporization point 103 may comprise a heated liquid injection module. In some other embodiments, vaporization point 103 may comprise a heated vaporizer. In yet other embodiments, vaporization point 103 may be eliminated from the process station. In some embodiments, a liquid flow controller (LFC) upstream of vaporization point 103 may be provided for controlling a mass flow of liquid for vaporization and delivery to process station 102.

Showerhead 106 may operate to distribute process gases and/or reactants (e.g., film precursors) toward substrate 112 at the process station, the flow of which may be controlled by one or more valves upstream from the showerhead (e.g., valves 120, 120A, 105). In the embodiment depicted in FIG. 1A, substrate 112 is depicted as located beneath showerhead 106, and is shown resting on a pedestal 108. Showerhead 106 may comprise any suitable shape, and may include any suitable number and arrangement of ports for distributing process gases to substrate 112. In some embodiments involving two or more stations, gas delivery system 101 includes valves or other flow control structures upstream from the showerhead, which can independently control the flow of process gases and/or reactants to each station so as to permit gas flow cut that to one station while prohibiting gas flow to a second station. Furthermore, gas delivery system 101 may be configured to independently control process gases and/or reactants delivered to each station in a multi-station apparatus such that the gas composition provided to different stations is different; e.g., the partial pressure of a gas component may vary between stations at the same time.

In FIG. 1A, volume 107 is depicted as being located beneath showerhead 106. In some embodiments, pedestal 108 may be raised or lowered to expose substrate 112 to volume 107 and/or to vary the size of volume 107. Optionally, pedestal 108 may be lowered and/or raised during portions of the deposition process to modulate process pressure, reactant concentration, etc., within volume 107. Showerhead 106 and pedestal 108 are depicted as being electrically coupled to radio frequency power supply 114 and matching network 116 for powering a plasma generator. Thus, showerhead 106 may function as an electrode for coupling radio frequency power into process station 102. In some embodiments, the plasma energy is controlled (e.g., via a system controller having appropriate machine-readable instructions and/or control logic) by controlling one or more of a process station pressure, a gas concentration, a RF power generator, and so forth. For example, radio frequency power supply 114 and matching network 116 may be operated at any suitable RF power level, which may operate to form plasma having a desired composition of radical species. In addition, RF power supply 114 may provide RF power having more than one frequency component, such as a low-frequency component (e.g., less than about 2 MHz) as well as a high frequency component (e.g., greater than about 2 MHz).

In some embodiments, plasma ignition and maintenance conditions are controlled with appropriate hardware and/or appropriate machine-readable instructions in a system controller which may provide control instructions via a sequence of input/output control (IOC) instructions. In one example, the instructions for bringing about ignition or maintaining a plasma are provided in the form of a plasma activation recipe of a process recipe. In some cases, process recipes may be sequentially arranged, so that at least some instructions for the process can be executed concurrently. In some embodiments, instructions for setting one or more plasma parameters may be included in a recipe preceding a plasma ignition process. For example, a first recipe may include instructions for setting a flow rate of an inert (e.g., helium) and/or a reactant gas, instructions for setting a plasma generator to a power set point and time delay instructions for the first recipe. A second, subsequent recipe may include instructions for enabling the plasma generator and time delay instructions for the second recipe. A third recipe may include instructions for disabling the plasma generator and time delay instructions for the third recipe. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain embodiments described herein, much shorter plasma strikes may be applied during a processing cycle. Such plasma strike durations may be on the order of less than about 50 milliseconds, with about 25 milliseconds being utilized in a specific example.

For simplicity, processing apparatus 100 is depicted in FIG. 1A as a standalone station (102) of a process chamber for maintaining a low-pressure environment. However, it may be appreciated that a plurality of process stations may be included in a multi-station processing tool environment, such as shown in FIG. 1B, which depicts a schematic view of an embodiment of a multi-station processing tool. Processing tool 150 employs an integrated circuit fabrication chamber 165 that includes multiple fabrication process stations, each of which may be used to perform processing operations on a substrate held in a wafer holder, such as pedestal 108 of FIG. 1A, at a particular process station. In the embodiment of FIG. 1B, the integrated circuit fabrication chamber 165 is shown having four process stations 151, 152, 153, and 154. Other similar multi-station processing apparatuses may have more or fewer process stations depending on the embodiment and, for instance, the desired level of parallel wafer processing, size/space constraints, cost constraints, etc. Also shown in FIG. 1B is substrate handler robot 175, which may operate under the control of system controller 190, configured to move substrates from a wafer cassette (not shown in FIG. 1B) from loading port 180 and into multi-station integrated circuit fabrication chamber 165, and onto one of process stations 151, 152, 153, and 154.

FIG. 1B also depicts an embodiment of a system controller 190 employed to control process conditions and hardware states of process tool 150. System controller 190 may include one or more memory devices, one or more mass storage devices, and one or more processors. The one or more processors may include a central processing unit, analog and/or digital input/output connections, stepper motor controller boards, etc. In some embodiments, system controller 190 controls all of the activities of process tool 150. System controller 190 executes system control software stored in a mass storage device, which may be loaded into a memory device, and executed by a processor of the system controller. Software to be executed by a processor of system controller 190 may include instructions for controlling the timing, mixture of gases, fabrication chamber and/or station pressure, fabrication chamber and/or station temperature, wafer temperature, substrate pedestal, chuck and/or susceptor position, number of cycles performed on one or more substrates, and other parameters of a particular process performed by process tool 150. These programed processes may include various types of processes including, but not limited to, processes related to determining an amount of accumulation on a surface of the chamber interior, processes related to deposition of film on substrates including numbers of cycles, determining and obtaining a number of compensated cycles, and processes related to cleaning the chamber. System control software, which may be executed by one or more processors of system controller 190, may be configured in any suitable way. For example, various process tool component subroutines or control objects may be written to control operation of the process tool components necessary to carry out various tool processes.

In some embodiments, software for execution by way of a processor of system controller 190 may include input/output control (IOC) sequencing instructions for controlling the various parameters described above. For example, each phase of deposition and deposition cycling of a substrate may include one or more instructions for execution by system controller 190. The instructions for setting process conditions for an ALD/CFD deposition process phase may be included in a corresponding ALD/CFD deposition recipe phase. In some embodiments, the recipe phases may be sequentially arranged, so that all instructions for a process phase are executed concurrently with that process phase.

Other computer software and/or programs stored on a mass storage device of system controller 190 and/or a memory device accessible to system controller 190 may be employed in some embodiments. Examples of programs or sections of programs for this purpose include a substrate positioning program, a process gas control program, a pressure control program, a heater control program, and a plasma control program. A substrate positioning program may include program code for process tool components that are used to load the substrate onto pedestal 108 (of FIG. 1A) and to control the spacing between the substrate and other parts of process tool 150. A positioning program may include instructions for appropriately moving substrates in and out of the reaction chamber as necessary to deposit films on substrates and clean the chamber.

A process gas control program may include code for controlling gas composition and flow rates and for flowing gas into one or more process stations prior to deposition to bring about stabilization of the pressure in the process station. In some embodiments, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing number of cycles on one or more substrates during the processing of the batch.

A heater control program may include code for controlling the current to heating unit 110 that is used to heat the substrate. Alternatively, the heater control program may control delivery of a heat transfer gas (such as helium) to the substrate.

In some embodiments, there may be a user interface associated with system controller 190. The user interface may include a display screen, graphical software displays of the apparatus and/or process conditions, and user input devices such as pointing devices, keyboards, touch screens, microphones, etc.

In some embodiments, parameters adjusted by system controller 190 may relate to process conditions. Non-limiting examples include process gas composition and flow rates, temperature, pressure, plasma conditions, etc. These parameters may be provided to the user in the form of a recipe, which may be entered utilizing the user interface. The recipe for an entire batch of substrates may include compensated cycle counts for one or more substrates within the batch in order to account for thickness trending over the course of processing the batch.

Signals for monitoring the process may be provided by analog and/or digital input connections of system controller 190 from various process tool sensors. The signals for controlling the process may be output by way of the analog and/or digital output connections of process tool 150. Non-limiting examples of process tool sensors that may be monitored include mass flow controllers, pressure sensors (such as manometers), thermocouples, etc. Sensors may also be included and used to monitor and determine the accumulation on one or more surfaces of the interior of the chamber and/or the thickness of a material layer on a substrate in the chamber. Appropriately programmed feedback and control algorithms may be used with data from these sensors to maintain process conditions.

System controller 190 may provide program instructions for implementing the above-described deposition processes. The program instructions may control a variety of process parameters, such as DC power level, pressure, temperature, number of cycles for a substrate, amount of accumulation on at least one surface of the chamber interior, etc. The instructions may control the parameters to operate in-situ deposition of film stacks according to various embodiments described herein.

For example, the system controller may include control logic for performing the techniques described herein, such as determining an amount of accumulated deposition material currently on at least an interior region of the deposition chamber interior, applying the amount of accumulated deposition material determined in (a), or a parameter derived therefrom, to a relationship between (i) a number of ALD cycles required to achieve a target deposition thickness, and (ii) a variable representing an amount of accumulated deposition material, in order to obtain a compensated number of ALD cycles for producing the target deposition thickness given the amount of accumulated deposition material currently on the interior region of the deposition chamber interior, and performing the compensated number of ALD cycles on one or more substrates in the batch of substrates. The system may also include control logic for determining that the accumulation in the chamber has reached an accumulation limit and stopping the processing of the batch of substrates in response to that determination, and for causing a cleaning of the chamber interior.

In addition to the above-identified functions and/or operations performed by system controller 190 of FIG. 1B, the controller may additionally control and/or manage the operations of RF power generator 195, which may convey RF power to multi-station integrated circuit fabrication chamber 165 via radio frequency input port 167. As described further herein, such operations may relate to determining upper and lower thresholds for RF power to be delivered to integrated circuit fabrication chamber 165, determining actual (such as real-time) levels of RF power delivered to integrated circuit fabrication chamber 165, RF power activation/deactivation times, RF power on/off duration, duty cycle, operating frequency, and so forth. Additionally, system controller 190 may determine a set of normal operating parameters of RF power to be delivered to integrated circuit fabrication chamber 165 by way of input port 167. Such parameters may include upper and lower thresholds of, for example, power reflected from one or more of input port 167 in terms of a reflection coefficient (e.g., the scattering parameter S₁₁), voltage standing wave ratio, upper and lower thresholds of a voltage applied to one or more of input port 167, upper and lower thresholds of current conducted through one or more of input port 167, as well as an upper threshold for a magnitude of a phase angle between a voltage and a current conducted through input port 167. Such thresholds may be utilized in defining “out-of-range” RF signal characteristics. For example, reflected power greater than an upper threshold may indicate an out-of-range RF power parameter. Likewise, an applied voltage or conducted current having a value below a lower threshold or greater than an upper threshold may indicate out-of-range RF signal characteristics. Similarly, a phase angle between an applied voltage and conducted current being greater than an upper threshold may indicate an out-of-range RF power parameter.

In particular embodiments, multi-station integrated circuit fabrication chamber 165 may comprise input ports in addition to input port 167 (additional input ports not shown in FIG. 1B). In particular embodiments, process stations of integrated circuit fabrication chamber 165 may utilize first and second input ports in which a first input port may convey a signal having a first frequency and in which a second input port may convey a signal having a second frequency. Use of two or more frequencies may bring about enhanced plasma characteristics, which may give rise to deposition rates within particular limits and/or more easily controlled deposition rates. Use of two or more frequencies may bring about other desirable consequences, and claimed subject matter is not limited in this respect. In certain embodiments, frequencies of between about 300 kHz and about 100 MHz may be utilized. In some embodiments, signal frequencies of about 2 MHz or less may be referred to as low frequency (LF) while frequencies greater than about 2 MHz may be referred to as high frequency (HF).

It may be appreciated that regardless of the frequencies of RF voltage and current signals coupled to multi-station integrated circuit fabrication chamber 165, it may be advantageous to measure such signals with an increased degree of precision. For example, for sinusoidal voltage and current signals that are in phase with each other, average RF power coupled to multi-station integrated circuit fabrication chamber 165 may be computed substantially in accordance with expression (1) below:

$${P}_{a νg} = \frac{1}{2} {V}_{peak} \times {I}_{peak} \qquad ( 1 )$$

Wherein Vₚₑₐₖ corresponds to a peak voltage signal and wherein Iₚₑₐₖ corresponds to a peak current signal. However, it may be appreciated that that expression (1) refers to a condition in which a sinusoidal voltage signal and a sinusoidal current signal are in phase with each other. Accordingly, to account for instances in which sinusoidal voltage signals and current signals are not in phase with each other, expression (2) may be utilized, in which:

$${P}_{a νg} = \frac{1}{2} {V}_{peak} \times {I}_{peak} cos ϕ \qquad ( 2 )$$

Wherein ϕ of expression (2) represents a phase angle between a voltage signal and a current signal.

Accordingly, from expression (2) it may be apparent that if a significant phase lag (ϕ) exists between the voltage and current signals, average power coupled to a fabrication chamber, such as multi-station integrated circuit fabrication chamber 165, may be decreased. For example, in response to a phase angle (ϕ) of 30° between voltage and current signals coupled to a fabrication chamber, P_{avg} may be reduced by approximately 13.4%. For more significant values of phase lag (ϕ), such as 60°, P_{avg} may be reduced by larger amounts, such as 50%. Further, for instances in which a phase angle (ϕ) between voltage and current signals approaches 90°, average power may be reduced to a negligible value (e.g., P_{avg}=0).

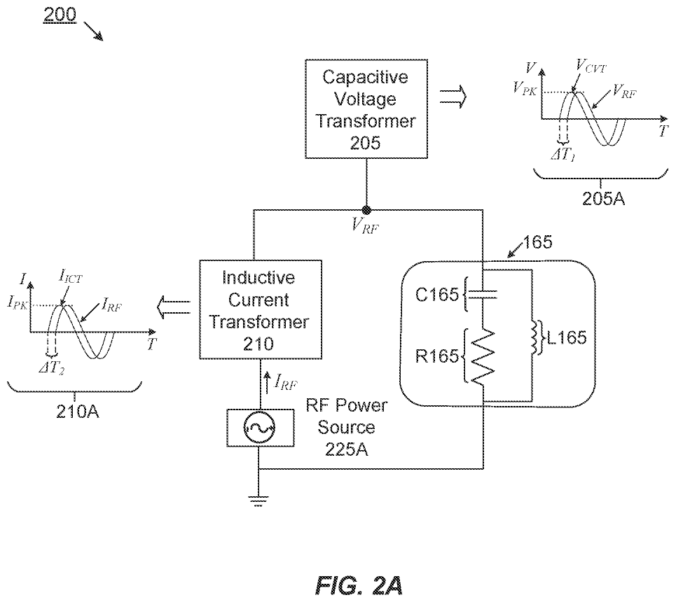

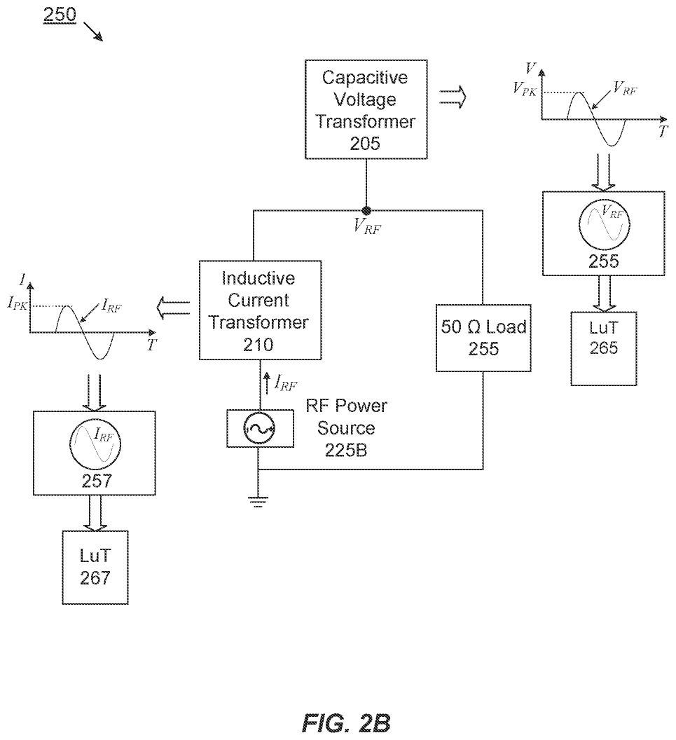

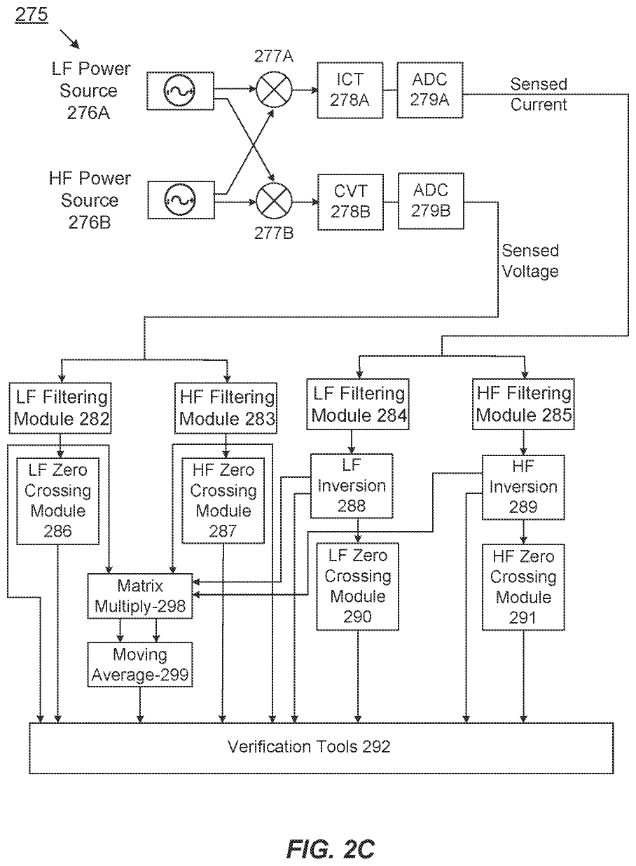

FIG. 2A is a schematic diagram showing phase lag in the measurement of a radio frequency (RF) signal, according to an embodiment 200. In embodiment 200, the complex impedance of multi-station integrated circuit fabrication chamber 165, may be modeled and/or characterized by an equivalent circuit that includes a series and/or parallel lumped circuit of capacitor C165 with resistor R165 and inductor L165. In some embodiments, the complex impedance of multi-station integrated circuit fabrication chamber 165 may comprise a capacitance having a value of between about 1.5 nF and about 3.5 nF and by a resistance of between about 5 ohms and about 10 ohms. In particular embodiments, capacitor C165 may comprise a value of about 2.15 nF and resistor R165 may comprise a value of about 7.89 ohms. However, claimed subject matter is intended to embrace any real or complex impedance, formed by series or parallel combinations of resistive and reactive circuit elements, presented by an integrated circuit fabrication chamber virtually without limitation. In certain embodiments, a complex impedance presented by multi-station integrated circuit fabrication chamber 165 may be dependent upon one or more reactive gases and/or vapors present in the chamber, partial and total pressures of gases, and other factors. Thus, for certain pressure/gas combinations, chamber 165 may present a predominantly capacitive load while for other pressure/gas combinations, chamber 165 may present a predominantly inductive load, for example.

In the embodiment of FIG. 2A, capacitive voltage transformer 205 may be coupled to a transmission line, such as a coaxial cable, for example, between RF power source 225A and multi-station integrated circuit fabrication chamber 165. In particular embodiments, capacitive voltage transformer 205 may represent a measurement sensor having a relatively high input impedance that occasionally or periodically samples a voltage at node V_{RF} shown in FIG. 2A without consuming a significant electric current. The embodiment of FIG. 2A may also include inductive current transformer 210, which may be coupled in series between RF power source 225A and multi-station integrated circuit fabrication chamber 165. In particular embodiments, inductive current transformer 210 may represent measurement sensor having a relatively low input impedance that occasionally or periodically samples a current conducted from RF power source 225A without bringing about any significant voltage drop.

In particular embodiments, RF power source 225A may operate to automatically (e.g., without user input) adjust a frequency of an output signal so as to maintain a desired output power level. Thus, in response to changes in input impedance presented by particular pressure/gas combinations within multi-station integrated circuit fabrication chamber 165, RF power source 225A may automatically tune to a nearby frequency, such as a frequency within ±10% of a selected frequency. Such automatic tuning of RF power source 225A may bring about a capability to deliver a relatively constant threshold amount of RF power even during conditions under which impedance presented by chamber 165 may be fluctuating between or among two or more values of real or complex impedance.

As shown in FIG. 2A, a voltage at node V_{RF} may be characterized as a conventional sinusoidal voltage, or as a complex sinusoidal signal, having a peak amplitude indicated by V_{PK} as depicted in graph 205A. Thus, in particular embodiments, V_{RF} may comprise a sinusoidal signal superimposed on a pulse train so as to allow intermittently pulsed sinusoidal signals to be applied to a fabrication chamber. Alternatively, in other embodiments, V_{RF} may comprise a sinusoidal signal of a first frequency superimposed on a pulse train wherein a sinusoidal signal of a second frequency is superimposed on the sinusoidal signal of the first frequency. Accordingly, V_{RF} of FIG. 2A is intended to represent any number of composite waveforms having pulsed (e.g., relatively square wave) components, saw-toothed (e.g., ramped) components, as well as any number of other components, and claimed subject matter is not limited in this respect.

FIG. 2A also shows graph 205A, which indicates that the voltage at node V_{RF} comprises a period corresponding to a frequency between, for example, about 300 kHz and about 100 MHz. Graph 205A also depicts a signal voltage measured by capacitive voltage transformer 205 (V_{CVT}), which is shown as lagging in phase with respect to voltage signal V_{RF} by an amount that corresponds to a time difference of ΔT₁. However, in other embodiments, a signal voltage measured by capacitive voltage transformer 205 may lead in phase with respect to voltage signal V_{RF}. In certain embodiments, such lagging or leading in phase may vary from between a few degrees, such as 3°, 5°, 10°, to a greater number of degrees, such as 25°, 30°, 45°, 60°, and so forth.

Similarly, graph 210A of FIG. 2A also depicts a sinusoidal electric current conducted through inductive current transformer 210. As shown in graph 210A, a RF current through inductive current transformer 210 (I_{RF}) comprises a peak current I_{PK} having a period corresponding to a frequency of between, for example, about 300 kHz and about 100 MHz as a unit with an additional ±10% (for example) frequency fine-tuning capability. Graph 210A also depicts a current signal measured by inductive current transformer 210 (I_{ICT}), which is shown as lagging in phase with respect to current signal I_{RF} by an amount that corresponds to a time difference ΔT₂. In certain embodiments, such lagging or leading in phase may vary from between a few degrees, such as 3°, 50°, 10°, to a greater number of degrees, such as 25°, 30°, 45° 60°, and so forth. However, in certain embodiments, components of inductive current transformer 210 may introduce a greater phase lag than capacitive voltage transformer 205. Thus, at least in some embodiments, ΔT₂>ΔT₁. In certain other embodiments, phase lag introduced by inductive current transformer 210 may comprise a much greater value than phase lag introduced by capacitive voltage transformer 205 (e.g., ΔT₂>>ΔT₁). In certain embodiments in which RF power source 225A generates signals having more than one frequency component, such as a low-frequency (LF) component and a high frequency (HF) component, ΔT₂ and ΔT₁ may include a frequency dependent component such that ΔT₁=ΔT_{1-LF}±ΔT_{1-HF} and ΔT₂=ΔT_{2-LF}±Δ_{2-HF}.

FIG. 2B is a schematic diagram showing an apparatus that may be utilized to characterize waveforms V_{RF} and I_{RF} of FIG. 2A according to an embodiment 250. It may be appreciated that the arrangement of FIG. 2B may be utilized to perform measurements of voltage and current characteristics of signals operating within a more controlled environment than the environment of FIG. 2A. Such an environment may correspond to an environment in which a reactive load representing a multi-station integrated circuit fabrication chamber has been replaced by a real-valued 50Ω load 265. It should be noted, however, that a controlled environment may utilize real-valued loads other than 50Ω, and claimed subject matter is not limited in this respect. In the more controlled environment of FIG. 2B, in addition to replacement of multi-station integrated circuit fabrication chamber 165 by 50Ω load 265, line lengths between RF power source 225A and inductive current transformer 210 and node V_{RF} may also be shortened so as to reduce parasitic reactances and/or transmission line effects that might bring about distortions in voltage and current measurements. Further, RF power source 225B, which may be used in lieu of RF power source 225A of FIG. 2A, may represent a tunable frequency source, which may be capable of providing a wide range of RF frequencies. For example, RF power source 225B may provide, for example, a wide variety of frequencies between about 300 kHz and about 100 MHz. Further, RF power source 225B may be capable of simultaneously generating a low frequency signal, such as a signal having a frequency below about 2 MHz, as well as a high frequency signal, such as a signal having a frequency greater than about 2 MHz.

Thus, in FIG. 2B, RF power source 225B may be tuned to a first value (e.g., about 300 kHz), and an output signal may be conveyed to inductive current transformer 210 and to capacitive voltage transformer 205. Characteristics of a waveform representing current I_{RF} may be measured utilizing inductive current transformer 210 and characteristics of a waveform representing V_{RF} may be measured by capacitive voltage transformer 205. In the embodiment of FIG. 2B, measurement scope 255 may function to digitize characteristics of the waveform representing current I_{RF} so that such digitized characteristics can be stored in lookup table (LuT) 295. In a similar manner measurement scope 257 may function to digitize characteristics of the waveform representing current IF so that such digitized characteristics can be stored in lookup table (LuT) 297. Such characteristics may comprise zero crossing information, peak voltage/current, distortion, phase/frequency noise, and/or any other parameters that may be used to characterize the waveforms representing current I_{RF} and voltage V_{RF}. Following storage of characteristics into lookup tables 295 and 297, RF power source 225B may be tuned to a second value (e.g., 301 kHz) and the above-described process of measurement, digitization, and storage into lookup tables 295 and 297 may be repeated.

FIG. 2C is a schematic diagram showing additional details of an apparatus used in developing a lookup table of values of phase lag introduced by devices utilized in measurement of a RF signal, according to an embodiment 275 that utilizes a time domain approach. In a manner similar to that of FIG. 2B, the arrangement of components of FIG. 2C, represents a relatively controlled environment. In the embodiment of FIG. 2, which may include LF power source 276A and HF power source 276B generating signals to a matched (50Ω) load. Development of a lookup table of phase lag introduced by measurement equipment, such as capacitive voltage transformer 205 and inductive current transformer 210 of FIGS. 2A and 2B, may begin with generation of generation of RF power. In embodiment 275, LF power source 276A generates a relatively low-frequency signal (such as a signal having a frequency of less than about 2 MHz) and HF power source 276B generates a relatively high-frequency signal (such as a signal having a frequency of greater than about 2 MHz). Signals from LF power source 276A and HF power source 276B are combined, such as by combiner 277A and 277B, which may form composite signals that include both LF and HF signal components.

In the embodiment of FIG. 2C, an output signal from combiner 277A is coupled to an input signal port of inductive current transformer (ICT) 278A. An output port of inductive current transformer 278A is coupled to analog-to-digital converter 279A. In a similar manner, an output signal port from combiner 277B is coupled to an input signal port of capacitive voltage transformer (CVT) 278B. An output port of capacitive voltage transformer 278B is coupled to an input port of analog-to-digital voltage converter 279B. In particular embodiments, the coupling of the output signals from a ramp function generator may provide an approach toward determining instantaneous voltage and current amplitudes of a RF signal level in which a digitized value of a RF signal is compared against a ramp function (not shown in FIG. 2C) having a known amplitude-versus-time profile. Accordingly, measurement of a RF signal level over a short sampling period, immediately followed by measurement ramp function signal over a similar sampling period, may permit determination of a precise time at which the RF signal level was measured. Use of a ramp function, followed or preceded by measurement of a RF signal level, may provide an approach toward measurement of RF signal characteristics other than instantaneous voltage and current, and claimed subject matter is not limited in this respect.

Output signals from analog-to-digital converter 279A may be coupled to an input port of LF filtering module 284 and to an input port of HF filtering module 285. Likewise, output signals from analog-to-digital converter 279B may be coupled to an input port of LF filtering module 282 and to an input port of HF filtering module 283. In the embodiment of FIG. 2C, LF inversion module 288 and HF inversion module 289 may generate amounts of phase delay or phase lag, which may be added to digitized current signal outputs from analog-to-digital converter 279A.

In the context of this disclosure, it is recognized that in high-frequency domains, such as domains in which a frequency of operation exceeds about 50 kHz, inductive current and capacitive voltage sensors may be considered “invasive” in so far as the sensors introduce frequency-dependent alterations, which distort the measured quantity (e.g., current, voltage, electric field, magnetic field). Thus, also in this context, the process of nullifying/eliminating frequency-dependent effects including introduction of phase delay (phase lag) in signals output from a sensor is referred to as an inversion process. To verify that such nullifying/eliminating of frequency-dependent effects may be verified via verification tools 292, which may be utilized to determine when a match between output signals of LF inversion module 288 and LF zero crossing module 290 is obtained. Verification tools 292 may additionally determine when a match between HF inversion module 289 and HF zero crossing module 291 is obtained. When such matches are obtained, values for phase lag in the relatively controlled environment of FIG. 2C may be entered into a lookup table, such as a lookup table 267 of FIG. 2B.

In particular embodiments, and as previously mentioned herein, phase lag introduced by an inductive current transformer may significantly exceed the phase lag introduced by a capacitive voltage transformer. Accordingly, in some embodiments, such as that of FIG. 2C, inversion modules may be utilized to provide phase lag correction (such as automatic phase lag correction) of digitized current signals only, utilizing LF inversion module 288 and HF inversion module 289. Thus, matrix multiply module 298 may perform matrix multiplication operations to determine LF power by multiplying output signals from LF filtering module 282 with output signals from LF inversion module 288 to determine instantaneous LF power. Likewise, matrix multiply module 298 may determine HF power by multiplying output signals from HF filtering module 283 with output signals from HF inversion module 289 to determine instantaneous HF power. Moving average module 299 may be utilized to determine an estimated average or steady state power over a period of time.

In such instances, verification tools 292 may operate to perform comparisons between output signals from LF filtering module 282 and output signals from LF zero crossing module 286. Similarly, verification tools 292 may perform comparisons between output signals from HF filtering module 283 and HF zero crossing module 287. Further, verification tools 292 may be utilized to determine accuracy of steady-state power measurements performed by moving average module 299.

Accordingly, returning now to FIG. 2A, which may represent measurement of voltage and current waveforms measured by capacitive voltage transformer 205 and inductive current transformer 210, waveform characteristics stored in lookup table 295 and lookup table 297 of FIG. 2B may be subtracted from waveform characteristics measured in response to RF signals being coupled to multi-station integrated circuit fabrication chamber 165. In particular embodiments, such subtractions may allow computation of phase lag (e.g., ΔT₁, ΔT₂) between the measured zero crossing of a current or voltage signal coupled to the multi-station integrated circuit fabrication chamber of FIG. 2A with respect to the measured zero crossing of a current or voltage signal coupled to a purely real impedance, such as 50Ω load 265 of FIG. 2B.

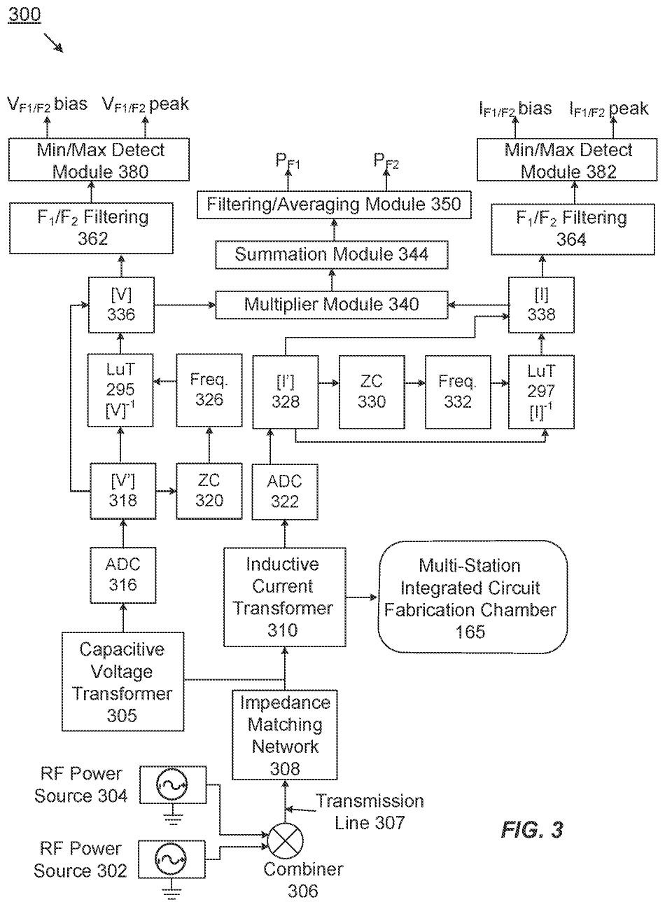

FIG. 3 is a schematic diagram of an apparatus used in RF power measurement in a multi-station integrated circuit fabrication chamber, according to an embodiment 300 that utilizes a time domain approach. It should be noted that lookup tables 295 and 297, computed utilizing the apparatus of FIG. 2C, are utilized in computing phase lag of RF signal characteristics measured utilizing the apparatus of FIG. 3. RF power sources 302 and 304 of FIG. 3 may represent RF power sources capable of generating, for example, between about 1 kW and about 10 kW. However, in other embodiments, RF power sources 302 and 304 may generate less than about 1 kW, such as about 500 W, about 750 W, and so forth. In still other embodiments, RF power sources 302 and 304 may generate greater than about 10 kW, such as about 12 kW, about 15 kW, about 20 20 kW, and so forth. In addition, RF power sources 302 and 304 may generate RF power at frequencies of between about 300 kHz and about 100 MHz, for example, although claimed subject matter is intended to embrace RF power sources of any useful frequency. In particular embodiments, RF power source 302 may generate a signal having a frequency of about 400 kHz, and RF power source 304 may generate a signal having a frequency of about 13.56 MHz.

In particular embodiments, RF power sources 302 and 304 may operate to automatically (e.g., without user input) adjust frequency of an output signal so as to maintain a desired output power level. Thus, in response to changes in input impedance presented by particular pressure/gas combinations within multi-station integrated circuit fabrication chamber 165, for example, RF power sources 302 and 304 may automatically tune to a nearby frequency, such as a frequency within +10%/o of a selected frequency. Such automatic tuning of RF power sources 302 and 304 may bring about a capability to deliver a relatively constant threshold amount of RF power even during conditions under which impedance presented by chamber 165 may be fluctuating between or among two or more values of real or complex impedance.

Signals from RF power sources 302 and 304 may be combined using combiner 306, which may operate to combine output signals from the RF power sources for transmission along a single transmission line, such as a single coaxial cable, for example. Output signals from combiner 306 may be coupled to an input port of impedance matching network 308, which may operate to match the impedance of inductive current transformer 310 and multi-station integrated circuit fabrication chamber 165 to the characteristic impedance of transmission line 307. In particular embodiments, impedance matching network 308 may include reactive components, such as inductors and capacitors arranged according to various circuit topologies, which may operate to maximize power transferred from combiner 306 to inductive current transformer 310 and multi-station integrated circuit fabrication chamber 165. In particular embodiments, matching network 308 may operate to reduce a voltage standing wave ratio (VSWR) on transmission line 307 to below a threshold value (e.g., 1.25:1, 1.5:1, 1.75:1, etc.).

In the embodiment of FIG. 3, inductive current transformer may present a negligible series impedance to RF signals from impedance matching network 308. In particular embodiments, inductive current transformer 310 may utilize a small series resistance, which may permit current to be computed via computing a voltage drop across the small series resistance. Accordingly, at least in particular embodiments, RF currents from impedance matching network 308 may not be significantly impeded by the presence of inductive current transformer 310. It may be appreciated that, at least in particular embodiments, and inductive current transformer operates to transform a high-amplitude current signal into a low-amplitude voltage signal. Such transformation utilizes a frequency-dependent transfer function, which also represents a phase lag introduced by the inductive current transformer. In a validation set up, such as described in reference to FIG. 3, this frequency response function may be evaluated and a lookup table (LuT) may be generated to perform the inversion. It should be noted that entries in the lookup table may include entries corresponding to a time domain values or frequency domain values, so as to permit inversion of a sensor frequency response function utilizing either time domain parameters or frequency domain parameters.

Capacitive voltage transformer 305, in contrast, may present a high impedance (such as a virtually infinite impedance) to RF signals from impedance matching network 308. Thus, RF voltage signals from impedance matching network 308 may not be significantly altered by the presence of capacitive voltage transformer 305. In particular embodiments, a capacitive voltage transformer may operate to transform a high-amplitude voltage signal into a low-voltage signal. Such transformation utilizes a frequency-dependent transfer function, which may reflect parasitic inductances, which also represent phase lag introduced by the capacitive voltage transformer. In a validation set up, such as described in reference to FIG. 3, this frequency response function may be evaluated in the lookup table may be generated to perform the inversion. In response to sampling of RF current by way of inductive current transformer 310 and in response to sampling of RF voltage by way of capacitive voltage transformer 305, RF signals may be conveyed to an input port of multi-station integrated circuit fabrication chamber 165.

An output port of capacitive voltage transformer 305 is coupled to an input port of analog-to-digital converter 316. Similarly, an output port of inductive current transformer 310 is coupled to an input port of analog-to-digital converter 322. In particular embodiments, analog-to-digital converters 316 and 322 utilize a successive-approximation approach in which an input signal is held steady by a sample-and-hold circuit while a flash analog-to-digital converter quantizes the sampled signal into a relatively small number of binary digits (e.g., 3 binary digits). The binary digits are then coupled to a digital-to-analog converter, which may be accurate to, for example, 12 binary digits. An analog output signal from the digital-to-analog converter may then be subtracted from the input signal to the analog-to-digital converter (316 or 322). The difference between the analog output signal from the digital-to-analog converter and the input signal to the analog-to-digital converter, which may be considered a “residue,” is amplified and coupled to a subsequent stage of the analog-to-digital converter, and the above-described process may be repeated. In such a successive-approximation architecture, the amplified residue is conveyed through successive stages of the converter, thereby providing small number of binary digits at each stage (e.g., 3 binary digits) until the residue reaches a subsequent flash analog-to-digital converter which operates to resolve the least-significant binary digits.

It should be noted that although analog-to-digital converters 316/322 are described as employing a successive-approximation architecture, in other embodiments, alternative architectures may be utilized. For example, in some embodiments, an analog-to-digital converter architecture may be selected after performing a trade-off analysis, which may balance accuracy with frequency performance. Accordingly, in particular embodiments, an analog-to-digital converter may utilize a pipelined architecture or any other conventional or unconventional architecture according to particular system parameters and requirements.

Digitized measurements of a voltage signal from analog-to-digital converter 316 may be loaded into a first matrix, depicted as [V′] 318 in FIG. 3, which includes digitized voltage values as measured by capacitive voltage transformer 305. Similarly, digitized measurements of a current signal from analog-to-digital converter 322 may be loaded into a second matrix, depicted as [I′]328 in FIG. 3, which includes digitized current values measured by inductive current transformer 310. To detect the zero crossing of digitized voltages, zero crossing (ZC) module 320 is utilized. An output signal from zero crossing module 320 is coupled to an input port of frequency module 326, which may utilize zero crossing characteristics of a voltage signal to determine a precise operating frequency of one or more of RF power sources 302/304. In a similar manner, to detect the zero crossing of digitized currents, zero crossing (ZC) module 330 may be utilized. It should be noted that although embodiment 300 utilizes signals from zero crossing modules 320 and 330 in the determination of sensor response characteristics, other techniques may be utilized to determine sensor response characteristics and/or auto correct of phase lag, and claimed subject matter is not limited in this respect.

An output signal from zero crossing module 330 is coupled to an input port of frequency module 332, which may operate to utilize zero crossing characteristics of the current signal to determine a precise operating frequency of one or more of RF power sources 302/304. In particular embodiments, zero crossing modules 320 and 330 may operate by determining a period in between successive zero crossings of a digitized signal, multiplying by a factor of 2, and computing the reciprocal of the determined period. It should be noted that although the embodiment of FIG. 3, as well as other embodiments described herein, utilize zero crossing modules that operate to determine when a signal crosses a RF ground (e.g., 0 V), in other embodiments, zero crossing modules may operate to determine when a signal crosses below any convenient reference voltage level, and claimed subject matter is not so limited.

Lookup tables 295 and 297, which store characterized voltage and current waveforms determined in the more controlled environment of FIG. 2B, may be utilized to provide a basis of comparison for zero crossing characteristics of digitized signals measured utilizing the apparatus of FIG. 3. Accordingly, in response to performing a comparison operation between digitized zero crossing values stored in lookup table 295 and digitized zero crossing values computed via frequency module 326, a voltage signal phase lag may be computed. In the embodiment of FIG. 3, values for voltage signal phase lag may be arranged in the form of a N×2 matrix, which may comprise a form that is substantially in accordance with expression (3), below:

$$[ \begin{matrix}{F}_{1} : & 0.1 ° \\ {F}_{2} : & 0.2 ° \\ {F}_{3} : & 0.1 °\end{matrix} ] \qquad ( 3 )$$

However, in other embodiments, values for voltage signal phase lag may be arranged in the form of N×2 matrix that may be arranged in terms of frequency and corresponding phase lags expressed in terms of units of time, so as to comprise a form substantially in accordance with expression (4) below:

$$[ \begin{matrix}{F}_{1} : & 1 \times {10}^{- 6} sec \\ {F}_{2} : & 1.1 \times {10}^{- 6} sec \\ {F}_{3} : & 1.2 \times {10}^{- 6} sec\end{matrix} ] \qquad ( 4 )$$

In addition, in other embodiments, values for voltage signal phase lag may be arranged in the form of N×2 matrix that may be arranged in terms of frequencies and corresponding phase lags expressed in terms of clock cycles, so as to comprise a form substantially in accordance with expression (5) below:

$$[ \begin{matrix}{F}_{1} : & 100 \times ( clock ) \\ {F}_{2} : & 120 \times ( clock ) \\ {F}_{3} : & 200 \times ( clock )\end{matrix} ] \qquad ( 5 )$$

Likewise, values for current signal phase lag may be arranged as a function of frequency in the form of a N×2 matrix, which are stored in matrix 338 [I]. Further, arrangement of current signal phase lag as a function of frequency may be similar to the voltage phase lag matrices of expressions (3), (4), and (5). In particular embodiments, values for current signal phase lag may exceed those of voltage signal phase lag.

In response to determining voltage, phase-corrected values for digitized voltage may be stored in corrected voltage signal matrix 336 [V]. Similarly, phase-corrected values for digitized current may be stored in corrected current signal matrix 338 [I]. Phase-corrected voltage and current values may be coupled to input ports of multiplier module 340. Multiplier module 340 may compute average RF power utilizing expression (2), repeated here for convenience:

$${P}_{avg} = \frac{1}{2} {V}_{peak} \times {I}_{peak} cos ϕ \qquad ( 2 )$$

Wherein ϕ of expression (2) represents a phase angle between a voltage signal and a current signal. Thus, since phase angle ϕ has been accurately determined in accordance with the above-described components of FIG. 3, an accurate average power may now be computed. In particular embodiments, multiplier module 340 may perform a succession of computations, utilizing corrected instantaneous voltages and corrected instantaneous currents, to arrive at an average power involving measurements performed during one or more complete periods of a voltage and current waveform. Computations of individual power measurements may be summed via summation module 344 and averaged via filtering/averaging module 350, which may function to remove effects of spurious noise or other artifacts present in digitized voltage and current values. In, which may be summed, via a summation module 344, and averaged via filtering/averaging module 350. Filtering/averaging module 350 may also operate to determine contributions of first and second frequencies, such as frequencies generated by RF power sources 302 and 304, to an overall average power.

Digitized voltage values stored in voltage signal matrix 336 may be utilized by F₁/F₂ filtering module 362 to separate frequency components into constituent components (e.g., first and second frequencies). Min/max detect module 380 may then operate to determine, for example, DC bias present in digitized voltages. Mm/max detect module 380 may additionally operate to determine peak voltage values present in digitized voltages. In a similar manner, digitized current values stored in current signal matrix 338 may be utilized by F₁/F₂ filtering module 364 bring about separation of frequency components into constituent components (e.g., first and second frequencies). Min/max detect module 382 may then operate to determine, for example, DC bias present in digitized currents. Min/max detect module 382 may additionally operate to determine peak current values present in digitized currents.

Thus, the apparatus of FIG. 3 provides a capability to perform real-time computation of power delivered to a multi-station integrated circuit fabrication chamber utilizing phase-corrected instantaneous voltage and phase-corrected instantaneous current. Thus, rather than determining an average value for current conducted to a fabrication chamber (e.g., integrated over a duration) for multiplication with an average value of voltage applied to a fabrication chamber (e.g., integrated over a duration), which may result in an average power integrated over the duration, real-time voltage and current measurements may be utilized to provide a real-time, instantaneous value of delivered power. Accordingly, power from a power generator may be rapidly modified (e.g., increased or decreased in real time) responsive to measurements of instantaneous current and voltage.

It should be noted that in particular embodiments, the embodiment of FIG. 3 may be modified to utilize certain computational alternatives, which may reduce computing time and computational complexity. For example, in one or more embodiments, in lieu of performing zero crossing operations, which may be utilized to determine frequency and, in turn, to determine lookup table values, linear or polynomial-based curve fitting techniques may be employed. In one or more other embodiments, a hybrid approach may be utilized, for example, in which for certain frequencies, the operations detailed in the description of FIG. 3 are performed, while for other frequencies, computational shortcuts, such as linear or polynomial-based curve fitting techniques may be employed. Claimed subject matter is intended to embrace both such approaches toward determination of phase lag in radio frequency signal sensors.

It should be noted that although certain embodiments described herein involve detection of zero crossing of current and voltage signals, (e.g., utilizing zero crossing modules 320 and 330) nulling of phase lag of a sensor may be performed via other approaches. However, regardless of an approach utilized to characterize a sensor's frequency response, such response can be represented in a frequency domain in a closed form, such as when the sensor's frequency response is relatively simple. In some instances, a closed form expression of a sensor's frequency response may involve first or second order lags, such as may be found responsive to use of a low-pass filter. In other instances, a frequency response may be represented via a Fast Fourier Transform when a sensor's frequency response cannot be conveniently described via a closed form expression. Responsive to determination of a sensor's frequency response, such response may then be inverted, such as via inversion of a closed form expression or by way of inverting of a matrix representation of the sensor's frequency response. Accordingly, the inverted representation of the sensor's frequency response may be applied to a signal, which may operate to remove or counteract (at least in part) the effects of phase lag introduced by the sensor.

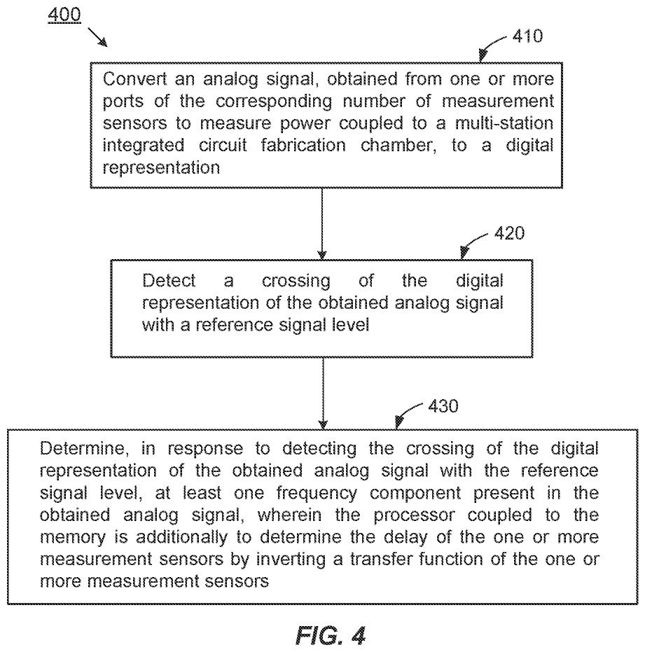

FIG. 4 is a flowchart for a method of determining a phase lag of one or more measurement sensors, according to an embodiment 400 that utilizes a time domain approach. It should be noted that claimed subject matter is intended to embrace variations of FIG. 4, including methods that include actions in addition to those of FIG. 4, actions performed in an order different than those of FIG. 4, as well as methods including fewer steps than those shown in FIG. 4. In addition, although the apparatus of FIG. 3 may be suitable for performing the method of FIG. 4, the method may be performed by other apparatuses, systems, or arrangements, and claimed subject matter is not limited in this respect. The method of FIG. 4 may begin at 410, which may include converting an analog signal, obtained from one or more ports of a corresponding number of measurement sensors, to measure power coupled to a multi-station integrated circuit fabrication chamber, to a digital representation. Conversion of an analog signal to a digital representation may involve use of an analog-to-digital converter, such as analog-to-digital converters 316/322 of FIG. 3. Analog-to-digital converters may utilize a pipelined architecture, a successive-approximation architecture, or any other conventional or unconventional architecture, and claimed subject matter is not limited in this respect. Measurement sensors may comprise current and voltage measurement sensors, such as inductive current transformers, capacitive voltage transformers, etc. In an alternative embodiment, measurement sensors may comprise magnetic field sensors, electric field sensors, or any other type of sensor.

The method may continue at 420, which may involve detection of a crossing of a digital representation of the obtained analog signal with a digital or analog representation of a reference signal level. In certain embodiments, a reference signal level may correspond to a RF signal ground, in which case 420 may involve use of a zero-crossing detector, such as zero crossing detectors 320/330 of FIG. 3. The method may continue at 430, which may include determining, in response to detecting the crossing of the digital representation of the obtained analog signal with a reference signal level, at least one frequency component present in the obtained analog signal, wherein the processor coupled to the memory is additionally to null out the phase lag of the one or more measurement sensors through inversion of a frequency response function of the one or more measurement sensors. In particular embodiments, inversion of a frequency response function of a measurement sensor may comprise comparing a digitized output signal of a sensor, measured under relatively controlled circumstances, with a digitized output of the sensor measured under circumstances corresponding to delivery of RF power to a multi-station integrated circuit fabrication chamber.

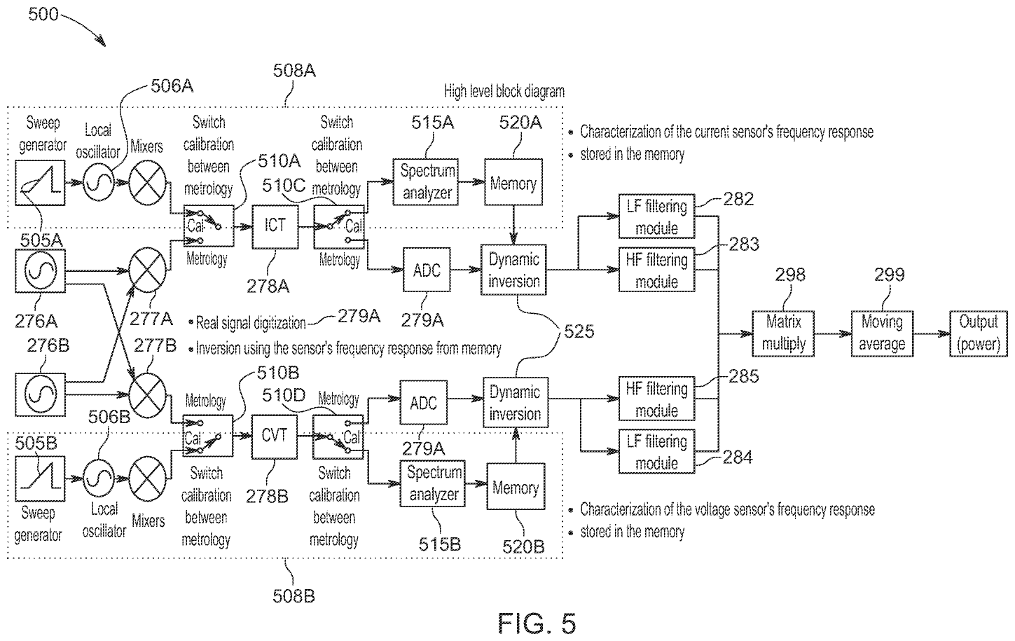

FIG. 5 is a high-level schematic diagram of an apparatus used in RF power measurement in a multi-station integrated circuit fabrication chamber according to an embodiment 500 that utilizes a frequency domain approach. FIG. 5 illustrates four signal paths, in which sweep generators 505A and 505B lie within dotted lines 508A and 508B representing calibration arrangements. In the upper left and lower left portions of FIG. 5, sweep generators 505A and 505B may correspond to frequency generators for generating a broad range of frequencies, for example, such as frequencies from substantially 0 Hz (direct-current) up to signals having frequencies in the in the gigahertz range, such as 1 GHz, 2 GHz, etc. In some embodiments, one or more of sweep generators 505A and 505B may represent a collection of frequency generators that generate discrete frequencies, such as 300 kHz, 400 kHz, 1 MHz, 2 MHz, 13.56 MHz, 27.12 MHz, and so forth. Output signals from sweep generators 505A and 505B may be coupled to (or directly passed through) local oscillators 506A and 506B. In some embodiments, local oscillators 506A and 506B may represent oscillators having a fixed frequency of, for example, at least several times greater than the highest frequency generated by sweep generator 505A/505B. Accordingly, for example, when sweep generator 505A and/or 505B generates a highest frequency of 100 MHz, local oscillator 506A/506B may generate a frequency of 400 MHz, 500 MHz, 920 MHz, etc. In some embodiments, frequency of local oscillators 506A/507B may be selected to satisfy a Nyquist sampling criteria so as to preclude under sampling in downstream processes. Mixers shown in FIG. 5, such as mixers 277A and 277B, thus receive a complex signal, which may include a frequency generated by sweep generators 505A and 505B as well as signals generated by local oscillators 506A and 506B.

In the embodiment of FIG. 5, the calibration arrangements that lie within dotted lines 508A and 508B also include switches 510A and 510B, which permits switching between calibration position and on-tool metrology position. In the example of FIG. 5, switch 510A is switched to a calibration position, in which signals flow from sweep generator 505A, through local oscillator 506A, through one of mixers 277A, and to an input port of ICT 278A. Also an example of FIG. 5, switch 510B is switched to a calibration position, in which signals flow from sweep generator 505B, through local oscillator 506B, through one of mixers 270 7B, and to an input port of CVT 278B. Accordingly, such arrangements permit calibration signals to be received by ICT 278A and CVT 278B. In addition, and also as shown in FIG. 5, switches 510C and 510D are shown as routing signals from ICT 278A and CVT 278B to spectrum analyzers 515 and 515 B (respectively). Thus, in a calibration environment, spectrum analyzers 515A and 515B allow representations, such as digital representations, of signals from TCT 278A and CVT 278B to be stored in memory 520A and 520B. It should be noted that in lieu of switches 510A, 510B, 510C, and 510D, switching logic, which may be implemented via a computing device, may perform equivalent switching functions.

In the embodiment of FIG. 5, responsive to switches 510A, 510B, 510C, and 510D being switched to a second position, which corresponds to an on-tool metrology position, signals from ICT 278A and CVT 278B, can be measured beginning with analog-to-digital converter 279A. Responsive to analog-to-digital conversion of signals from ICT 278A and CVT 278B, dynamic inversion module 525 operates to utilize correction factors generated during calibration, such as calibration factors stored in memory 520A and 520B to perform characterization of ICT 278A and CVT 278B during, for example, deposition or etch processes. In some embodiments, dynamic inversion module 525 performs a division (or multiplication by an inverse) process beginning with determination of the transfer function for ICT 278A and CVT 278B stored within memory 520A and 520B measured during calibration of ICT 278A and CVT 278B. During a calibration operation, a transfer function for CVT 278B can be determined substantially in accordance with expression (6):

V_{measured}(f)=Vₜᵣᵤₑ(f)×H_{CVT}(f) (6)

Similarly, during a calibration operation, a transfer function for ICT 278A can be determined substantially in accordance with expression (7):

I_{measured}(f)=Iₜᵣᵤₑ(f)×H_{ICT}(f) (7)

Thus, from expression (6) and (7) it may be recognized that to determine phase-corrected values (such as automatically phase-corrected values) for measured current and measured voltage, and inversion operation (e.g., division, or multiplication by an inverse) can be performed. Thus, rearranging expressions (6) and (7), expressions (8) and (9) can be formed, as follows:

$${V}_{true} ( f ) = \frac{{V}_{measured} ( f )}{{H}_{CVT} ( f )} \qquad ( 8 )$$

$${I}_{true} ( f ) = \frac{{I}_{measured} ( f )}{{H}_{ICT} ( f )} \qquad ( 9 )$$

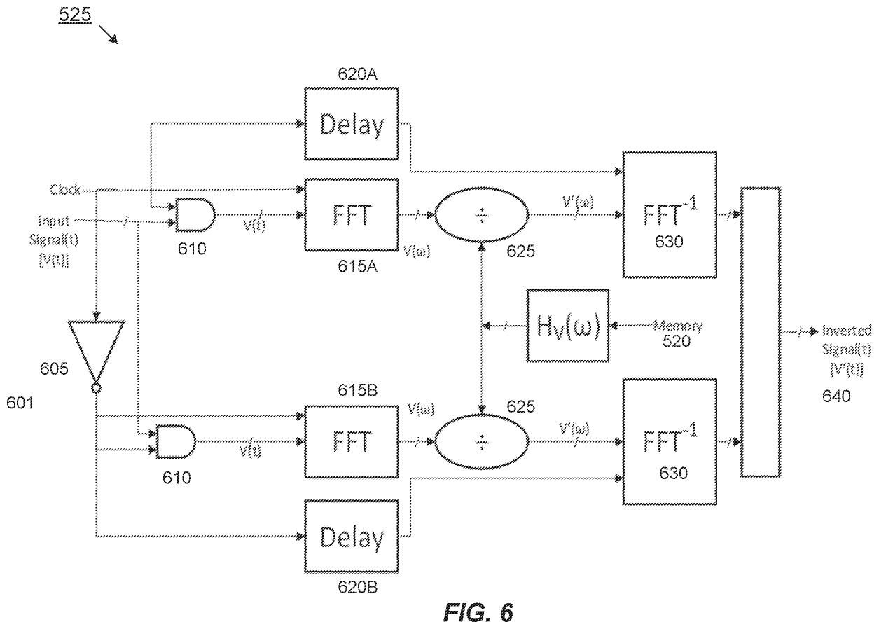

FIG. 6 is a schematic diagram of an apparatus used to perform digital inversion (e.g., division or multiplication by an inverse) of measurement signals from a multi-station integrated circuit fabrication chamber according to an embodiment (600) that utilizes a frequency domain approach. In particular embodiments, the schematic diagram of FIG. 6 performs inversion of measured voltage and current signals, which includes performing a division (or multiplication by an inverse) operation of the measured voltage and current signals by the transfer function determined responsive to switches 510A, 510B, 510C, and 510D being switched to the “calibration” setting. In FIG. 6, a clock input signal 601 is shown as being coupled to Fast Fourier transform (FFT) module 615 and to delay circuit 620. Additionally, clock input signal 601 is coupled to an input port of inverter logic element 605 and to AND gate 610. Thus, responsive to clock input signal 601 assuming a positive voltage, such as during a positive portion of a clock cycle, FFT module 615A operates to determine the frequency content of the input signal as a function of time (V(t)). Conversely, responsive to clock input signal 601 assuming a negative voltage, such as during a negative portion of a clock cycle, FFT module 615B operates to determine the frequency content of the input signal V(t). Thus, FFT modules of 615A and 615B function to alternatively process a portion of the input signal V(t).

It should be noted that although not explicitly shown in FIG. 6, an equivalent architecture of FIG. 6 may operate to determine the frequency content of an input current signal, which could be represented as (I(t)). Accordingly, rather than inverting a voltage transfer function Hν(ω), an equivalent architecture may operate to invert a current transfer function Iν(ω).

As shown in FIG. 6, delay circuit 620A operates in parallel with FFT module 615A. Similarly, delay circuit 620B operates in parallel with FFT module 615B. In some embodiments, use of delay circuits 620A and 620B have been determined to improve the accuracy of the circuit shown in the schematic diagram of FIG. 6. In some instances, responsive to Fast Fourier transform computation of input signal waveforms (e.g., V(t)), such as performed by FFT modules 615A and 615B, being a relatively time-consuming process, delay circuits 620A and 620B provide some overlap between an input signal waveforms and a FFT representation. It may be appreciated that combination of output signals of FFT module 615A and output signals of delay circuit 620A (and the combination of output signals of FFT module 615B and output signals of delay circuit 620B) amount to the concatenation of the output signals in which the output signals of the delay circuit are concatenated with the output signals of the FFT module. In some embodiments, the use of delay circuits 620A and 620B, in parallel with FFT modules 615A and 615B, permits lower-cost and widely-available FFT modules having greater accuracy and speed than a single higher-speed FFT module.

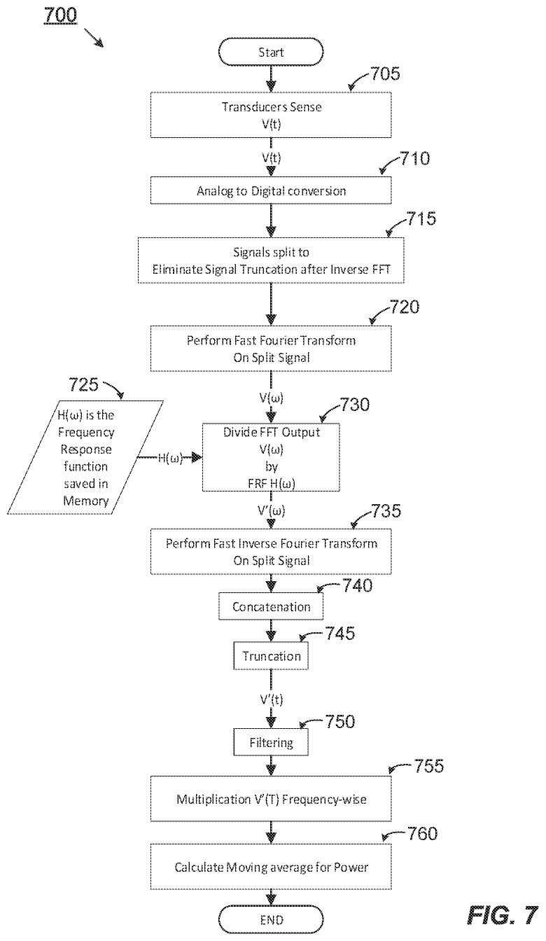

In response to a division (or multiplication by an inverse) operation (indicated at 625), an inverse Fast Fourier transform (FFT⁻¹) may be performed (such as by FFT⁻¹ module 630) on the resulting signal. In some embodiments, an inverse Fast Fourier transform may result in a digital representation of time domain signals representing Vₜᵣᵤₑ(f) and Iₜᵣᵤₑ(f) of expressions (8) and (9). The resulting inverted transfer function, in which the apparent effect of phase lag in V(t) and in I(t), are removed from the frequency-transformed representation of V(t) (e.g., Vₜᵣᵤₑ(f) in expression (8)) and from the frequency-transformed representation of I(t) (e.g., Iₜᵣᵤₑ(f) in expression (9). In response to inversion of the transfer function (e.g., H_{CVT}(f) and H_{ICT}(f)) of expressions (8) and (9), an analog representation of Vₜᵣᵤₑ(f) and Iₜᵣᵤₑ(f) is provided at an output port of digital-to-analog converter 640. As explained further with reference to FIG. 7, after determination of Vₜᵣᵤₑ(f) and Iₜᵣᵤₑ(f), the concatenated frequency-domain representations of Vₜᵣᵤₑ(f) and Iₜᵣᵤₑ(f) can be truncated so as to be pared down to, for example, a 16-bit representation (rather than, for example, 32-bit concatenated representations of Vₜᵣᵤₑ(f) and Iₜᵣᵤₑ(f)). However, at least in particular embodiments, truncation of Vₜᵣᵤₑ(f) and Iₜᵣᵤₑ(f) may utilize a sliding window truncation rather than a fixed-position truncation. In an example solely for the purposes of illustrating the sliding-window principle, if the lower 4 bits of an 8-bit digital word 01111111 (having a decimal value of 127) are to be truncated utilizing a standard technique, such technique would result in 01111111 being truncated to 0111 (having a decimal value of 112). However, if a sliding-window technique were utilized, the 8-bit digital word 01111111 would be truncated to 1111 (having a decimal value of 120). Accordingly, as illustrated via this simple and non-limiting example, truncation of concatenated frequency domain representations of Vₜᵣᵤₑ(f) and Iₜᵣᵤₑ(f) result in reducing binary word size with perhaps only minor degradations in accuracy.

Also as explained further in reference to FIG. 7, Vₜᵣᵤₑ(f) and Iₜᵣᵤₑ(f) may be filtered utilizing, for example, a low-pass filter, a high-pass filter, or a bandpass filter. In some embodiments, a low-pass filter for attenuating signals above about 5 MHz may separate low-frequency signals (e.g., signals having a frequency of about 400 kHz) from high-frequency signals (e.g. signals having a frequency of about 13.5 MHz). Also as explained further in reference to FIG. 7, Vₜᵣᵤₑ(f) and Iₜᵣᵤₑ(f) may be filtered utilizing a moving average filtering module (similar to moving average module 299) to determine an estimated average or steady state power over a period of time. In some embodiments, filtering via a moving average filter may reduce fluctuations brought about by rapid variations in computed power (resulting from multiplication of instantaneous values of Vₜᵣᵤₑ(f) and Iₜᵣᵤₑ(f)). Thus, in some instances, a moving average filter having a time window of between about 100 μs (or more or less) to about 10 ms (or more or less) may operate to damp undesirably large fluctuations in computed power.

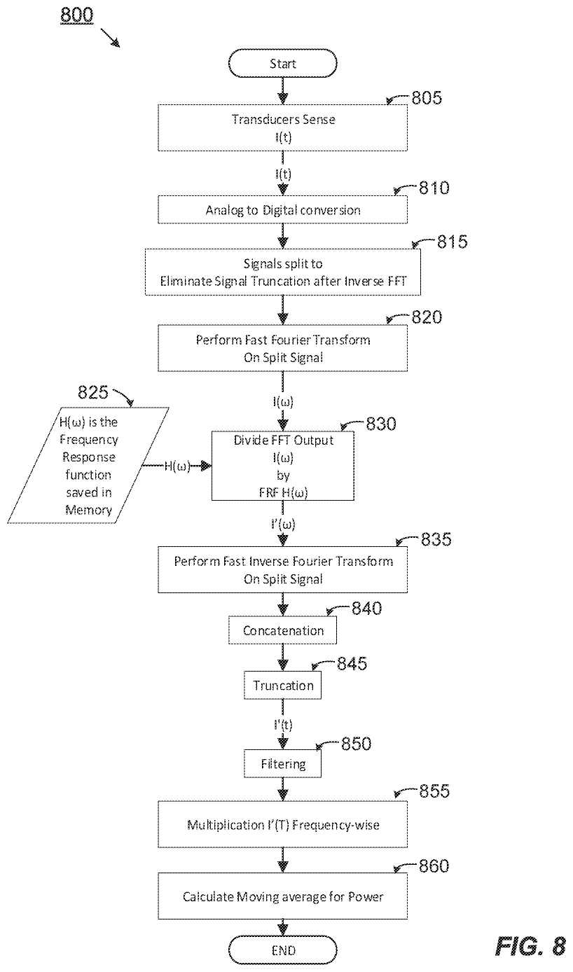

FIG. 7 is a flowchart for a method 700 of computing RF power from voltage signals from a multi-station integrated circuit fabrication chamber according to an embodiment that utilizes a frequency domain approach. It should be noted that claimed subject matter is intended to embrace variations of FIGS. 7 and 8, including methods that include actions in addition to those of FIGS. 7 and 8, actions performed in an order different than those of FIGS. 7 and 8, as well as methods including fewer steps than those shown. The method of FIG. 7 begins at block 705 which include sensing, such as by a transducer, of a voltage signal. Block 710 may include converting an analog signal (such as V(t)) to a digital representation of a voltage signal. The method may continue in block 715, which includes splitting or dividing signals, such as routing signals to first and second FFT modules (e.g. FFT modules 615A/615B of FIG. 6) during alternating portions of a clock cycle. The method may continue at block 720, which may include performing Fast Fourier transforms on signals divided or split responsive to block 715 to obtain of frequency-domain representation of a voltage signal (e.g., V(ω).

The method may continue at block 725, which may include accessing transfer function H(ω) values stored in a memory. In some embodiments, block 725 may involve accessing a memory, such as memory 520A and/or memory 520B of a spectrum analyzer, that contains a frequency-domain representation of a voltage sensor (e.g., Hν(ω)). Block 730 may include dividing (or multiplying by an inverse) the frequency-domain representation of a voltage signal ((e.g., V(ω)) by a frequency response function (e.g., voltage transfer function) a voltage sensor ((e.g., Hν(ω)). Block 735 may include performing an inverse Fast Fourier transform (FFT⁻¹) to arrive at a digital representation of phase-corrected signals from a voltage sensor. Block 740 may include concatenating delayed and non-delayed digital representations of phase-corrected signals from a voltage sensor. Block 745 may include truncating, such as by way of a sliding window, to reduce the bit length of the digital representations of phase-corrected signals from a voltage sensor. Block 750 may include filtering, such as utilizing a low-pass filter, to obtain frequency components, such as low-frequency components and high-frequency components. Block 755 may include performing matrix multiplication operations to determine LF power as well as performing matrix multiplication operations to determine HF power. Block 760 may include computing a moving average for power measurements resulting the matrix multiplication operations of block 755. Block 760 may include applying a moving average filter having a time window of between about 100 μs (or more or less) to about 10 ms (or more or less), which may operate to damp undesirably large fluctuations in computed power.

FIG. 8 is a flowchart for a method 800 of computing RF power from current measurement signals from a multi-station integrated circuit fabrication chamber according to an embodiment that utilizes a frequency domain approach. The method of FIG. 8 begins at block 805 which include sensing, such as by a transducer, of a current measurement signal. Block 810 may include converting an analog signal (such as I(t)) to a digital representation of a current measurement signal. The method may continue in block 815, which includes splitting or dividing signals, such as routing signals to first and second FFT modules (e.g., similar to FFT modules 615A/615B of FIG. 6) during alternating portions of a clock cycle. The method may continue at block 820, which may include performing a Fast Fourier transform on signals divided or split responsive to block 815 to obtain of frequency-domain representation of a current measurement signal (e.g., I(ω).

The method may continue at block 825, which may include accessing transfer function H(w) values stored in a memory. In some embodiments, block 825 may involve accessing a memory, such as memory 520A and/or memory 520B of a spectrum analyzer, that contains a frequency-domain representation of a current measurement signal (e.g., H_{I}(ω)). Block 830 may include dividing (or multiplying by an inverse) the frequency-domain representation of a current measurement signal ((e.g., I(ω)) by a frequency response function (e.g., current sensor transfer function, H_{I}(ω)). Block 835 may include performing an inverse Fast Fourier transform (FFT⁻¹) to arrive at a digital representation of phase-corrected signal from a current measurement sensor. Block 840 may include concatenating delayed and non-delayed digital representations of phase-corrected signals from a current measurement sensor. Block 845 may include truncating, such as by way of a sliding window, to reduce the bit length of the digital representations of phase-corrected signals from a current measurement sensor. Block 850 may include filtering, such as utilizing a low-pass filter, to obtain frequency components, such as low-frequency components and high-frequency components. Block 855 may include performing matrix multiplication operations to determine LF power as well as performing matrix multiplication operations to determine HF power. Block 860 may include computing a moving average for power measurements resulting from the matrix multiplication operations of block 855. Block 860 may include applying a moving average filter having a time window of between about 100 μs (or more or less) to about 10 ms (or more or less), which may operate to damp undesirably large fluctuations in computed power.

Referring back to FIG. 1B, system controller 190 may comprise a portion of a system, which may form a part of the apparatus of FIGS. 1A/1B. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the number of cycles performed on a substrate, the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers or field-programmable gate arrays (FPGA) or FPGA with system-on-a-chip (SoC) that that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In the foregoing detailed description, numerous specific details are set forth to provide a thorough understanding of the presented embodiments or embodiments. The disclosed embodiments or embodiments may be practiced without some or all of these specific details. In other instances, well-known process operations have not been described in detail so as to not unnecessarily obscure the disclosed embodiments or embodiments. While the disclosed embodiments or embodiments are described in conjunction with the specific embodiments or embodiments, it will be understood that such description is not intended to limit the disclosed embodiments or embodiments.

The foregoing detailed description is directed to certain embodiments or embodiments for the purposes of describing the disclosed aspects. However, the teachings herein can be applied and implemented in a multitude of different ways. In the foregoing detailed description, references are made to the accompanying drawings. Although the disclosed embodiments or embodiment are described in sufficient detail to enable one skilled in the art to practice the embodiments or embodiment, it is to be understood that these examples are not limiting; other embodiments or embodiment may be used and changes may be made to the disclosed embodiments or embodiment without departing from their spirit and scope. Additionally, it should be understood that the conjunction “or” is intended herein in the inclusive sense where appropriate unless otherwise indicated; for example, the phrase “A, B, or C” is intended to include the possibilities of “A,” “B,” “C,” “A and B,” “B and C,” “A and C,” and “A, B, and C.”

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically includes a diameter of 200 mm, or 300 mm, or 450 mm. The foregoing detailed description assumes embodiments or embodiments are implemented on a wafer, or in connection with processes associated with forming or fabricating a wafer. However, the claimed subject matter is not so limited. The work piece may be of various shapes, sizes, and materials. In addition to semiconductor wafers, other work pieces that may take advantage of claimed subject matter may include various articles such as printed circuit boards, or the fabrication of printed circuit boards, and the like.

Unless the context of this disclosure clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also generally include the plural or singular number respectively. When the word “or” is used in reference to a list of two or more items, that word covers all of the following interpretations of the word: any of the items in the list, all of the items in the list, and any combination of the items in the list. The term “embodiment” refers to implementations of techniques and methods described herein, as well as to physical objects that embody the structures and/or incorporate the techniques and/or methods described herein.

What is claimed is:

1. An apparatus, comprising:
one or more measurement sensors disposed to measure voltage applied to, or current coupled to, one or more process stations of the apparatus;
one or more analog-to-digital converters, coupled to an output port of a corresponding one of the one or more measurement sensors, to provide a digital representation of a radio frequency (RF) signal measured by the one or more measurement sensors; and
a processor configured to:
convert the digital representation of the RF signal measured by the one or more measurement sensors from a time domain to a frequency domain representation; and to
process the frequency domain representation of the RF signal by a sensor transfer function to invert a phase lag of the one or more measurement sensors.

2. The apparatus of claim 1, wherein the processor is configured to invert the phase lag of the one or more measurement sensors by multiplying an inverted transfer function of the one or more measurement sensors by a frequency response of the one or more measurement sensors.

3. The apparatus of claim 1, wherein the processor is configured to invert the phase lag of the one or more measurement sensors by dividing a transfer function of the one or more measurement sensors by a frequency response of the one or more measurement sensors.

4. The apparatus of claim 3, wherein the processor is configured to convert the digital representation of the RF signal measured by the one or more measurement sensors from a time domain to a frequency domain utilizing two or more Fast Fourier transform blocks arranged in parallel.

5. The apparatus of claim 4, wherein each of the two or more Fast Fourier transform blocks is arranged in parallel with a corresponding delay circuit.

6. The apparatus of claim 4, further comprising a digital inverter, wherein the digital inverter comprises a logic circuit to convey an output signal from the one or more measurement sensors to a first of the two or more Fast Fourier transform blocks during a first clock portion and to convey the output signal from the one or more measurement sensors to a second of the two or more Fast Fourier transform blocks during a second clock portion.

7. The apparatus of claim 4, wherein the digital inverter comprises a concatenation block configured to join output signal representations from the two or more Fast Fourier transform blocks arranged in parallel into a single output signal representation.

8. The apparatus of claim 7, further comprising a truncation block configured to truncate a size of the single output signal representation.

9. The apparatus of claim 8, wherein the truncation block comprises a sliding window configured to adjust binary digits of the single output signal representation.

10. The apparatus of claim 1, wherein the processor is configured to compute elements of a frequency response function during a calibration phase, and wherein inversion of the frequency response function to provide the phase lag of the one or more measurement sensors occurs during a process performed by the one or more process stations of the apparatus.

11. An apparatus configured to a null out of a measurement sensor, comprising:
one or more analog-to-digital converters, coupled to an output port of a corresponding one of one or more measurement sensors, to provide a digital representation of a radio frequency (RF) signal measured by the one or more measurement sensors; and
a processor, coupled to a memory, configured to convert the digital representation of the RF signal measured by the one or more measurement sensors from a first domain to a second domain and to process the signal converted to the second domain by a sensor transfer function to invert a phase lag of the one or more measurement sensors.

12. An apparatus adapted to null out a phase lag of one or more measurement sensors, comprising:
an analog-to-digital converter to convert an analog signal, obtained from one or more output ports of a corresponding number of the one or more measurement sensors to measure power coupled to a multi-station integrated circuit fabrication chamber, to a digital representation;
a detector to detect a frequency content of output signals of the one or more measurement sensors; and
a processor coupled to a memory to convert the digital representation of an RF signal measured by the one or more measurement sensors from a time domain to a frequency domain representation and process the frequency domain representation of the RF signal by a sensor transfer function to invert the phase lag of the one or more measurement sensors.

13. The apparatus of claim 12, wherein the detecting the frequency content of the output signals comprises determining a crossing of the digital representation of the output signal with a reference signal level; and
determine, utilizing the crossing of the digital representation of the signal measured by the one or more measurement sensors, a frequency content of the RF signal and the nulling-out of the phase lag of the one or more measurement sensors.

14. The apparatus of claim 13, wherein the crossing corresponds to a RF signal ground.

15. The apparatus of claim 12, wherein the one or more measurement sensors comprises a capacitive voltage transformer operating at any frequency between about 300 kHz and about 100 MHz.

16. The apparatus of claim 12, wherein the one or more measurement sensors comprises a current measurement sensor operating at a frequency of between about 300 kHz and about 100 MHz.

17. The apparatus of claim 12, wherein the nulling-out of phase lag of the one or more measurement sensors corresponds to canceling phase lag introduced by the one or more measurement sensors.

18. The apparatus of claim 17, wherein a frequency response forms a frequency response function.

19. The apparatus of claim 18, wherein the processor is further configured to provide an estimate of RF power coupled to the multi-station integrated circuit fabrication chamber utilizing a signal received from the one or more measurement sensors that is advanced by an amount corresponding to the phase lag.

20. An apparatus adapted to measure a current signal or voltage signal, comprising:
an analog-to-digital converter to convert an analog signal, obtained from one or more output ports of a corresponding number of one or more measurement sensors to measure power coupled to a multi-station integrated circuit fabrication chamber, to a digital representation;
a detector to detect a frequency content of output signals of the one or more measurement sensors; and
a processor coupled to a memory to determine, in response to detecting the frequency content of the output signals of the one or more measurement sensors, a frequency response function of the one or more measurement sensors, the processor coupled to the memory additionally to null out a phase lag of the one or more measurement sensors by inverting a frequency response function of the one or more measurement sensors.

21. The apparatus of claim 20, wherein the detecting the frequency content of the output signals of the one or more sensors comprises detecting a crossing of the digital representation of the obtained analog signal with a reference signal.

22. The apparatus of claim 21, wherein the reference signal corresponds to a radio frequency (RF) ground.

23. The apparatus of claim 22, wherein a first measurement sensor of the corresponding number of the one or more measurement sensors comprises a voltage measurement sensor.

24. The apparatus of claim 23, wherein a second measurement sensor of the corresponding number of measurement sensors comprises a current measurement sensor.

25. The apparatus of claim 24, wherein the processor applies a phase lag correction to measurements performed by the voltage measurement sensor and the current measurement sensor to obtain a corrected instantaneous voltage measurement and corrected instantaneous current measurement.

26. The apparatus of claim 20, wherein the processor further operates to compute RF power delivered to the multi-station integrated circuit fabrication chamber by computing a product of a corrected instantaneous voltage and a corrected instantaneous current.

27. The apparatus of claim 20, wherein the processor further operates to compute a moving average of successive computations of RF power delivered to the multi-station integrated circuit fabrication chamber to estimate average RF power delivered to the multi-station integrated circuit fabrication chamber.

28. The apparatus of claim 20, wherein the processor further operates to compute real-time power delivered to a multi-station integrated circuit fabrication chamber utilizing real-time phase-corrected instantaneous voltage and real-time phase-corrected instantaneous current.

29. The apparatus of claim 28, wherein the processor further operates to modify an amount of power generated by a power generator, for coupling to the multi-station integrated circuit fabrication chamber, responsive to computing the real-time power delivered.

30. The apparatus of claim 20, wherein the phase lag of the one or more measurement sensors is determined in terms of clock periods.

31. An apparatus to estimate radio frequency (RF) power coupled to a load, comprising:
a current sensor having a current sensor frequency response function and a voltage sensor having a voltage sensor frequency response function;
a first analog-to-digital converter coupled to an output port of the current sensor;
a second analog-to-digital converter coupled to an output port of the voltage sensor; and
a processor coupled to a memory to:
obtain digital representations of instantaneous current and to obtain digital representations of instantaneous voltage;
obtain a phase lag of the instantaneous current and the instantaneous voltage; and
invert the frequency response function of the current sensor and the frequency response function of the voltage sensor to counteract for the obtained phase lag of the instantaneous current and the instantaneous voltage.

32. The apparatus of claim 31, wherein the current sensor comprises an inductive current transformer.

33. The apparatus of claim 31, wherein the voltage sensor comprises a capacitive voltage transformer.

34. The apparatus of claim 31, wherein the current sensor and the voltage sensor operate at any frequency between about 300 kHz and about 100 MHz.

35. An apparatus adapted to determine a phase lag of one or more measurement sensors, comprising:
an analog-to digital converter to convert an analog signal, obtained from one or more output ports of a corresponding number of the one or more measurement sensors to measure power coupled to a multi-station integrated circuit fabrication chamber, to a digital representation;
a detector to detect a sensor response characteristic from the digital representation of the obtained analog signal; and
a processor coupled to a memory to determine, in response to detecting the sensor response characteristic, at least one frequency component present in the digital representation of the obtained analog signal, the processor coupled to the memory additionally to null out the phase lag of the one or more measurement sensors by inverting a frequency response function of the one or more measurement sensors.

36. The apparatus of claim 35, wherein the detector detects the sensor response characteristic by determining a crossing of the digital representation of the obtained analog signal with a reference signal.

37. The apparatus of claim 36, wherein the detector detects the sensor response characteristic utilizing an analog representation of the reference signal.

38. The apparatus of claim 36, wherein the detector detects the sensor response characteristic utilizing a digital representation of the reference signal.

39. The apparatus of claim 36, wherein the processor coupled to the memory determines the at least one frequency component present in the digital representation of the obtained analog signal in response to detecting the crossing of the digital representation of the obtained analog signal with the reference signal.

40. The apparatus of claim 35, wherein the processor coupled to the memory performs the inverting of the frequency response function of the one or more measurement sensors in a frequency domain.

41. The apparatus of claim 35, wherein the processor coupled to the memory performs the inverting of the frequency response function of the one or more measurement sensors in a time domain.
